(19) United States
(12) Patent Application Publication
(10) Pub. No.: US 2025/0198051 A1
(43) Pub. Date: Jun. 19, 2025

(54) NITRIDE CRYSTAL SUBSTRATE AND PRODUCTION METHOD FOR NITRIDE CRYSTAL SUBSTRATE

(71) Applicant: SUMITOMO CHEMICAL COMPANY, LIMITED, Tokyo (JP)

(72) Inventors: Taichiro KONNO, Hitachi-shi (JP); Masafumi YOKOYAMA, Hitachi-shi (JP); Hajime FUJIKURA, Hitachi-shi (JP)

(73) Assignee: SUMITOMO CHEMICAL COMPANY, LIMITED, Tokyo (JP)

(21) Appl. No.: 18/978,674

(22) Filed: Dec. 12, 2024

(30) Foreign Application Priority Data
Dec. 13, 2023 (JP) 2023-210383

(51) Int. Cl. C30B 29/40; C30B 25/18

(52) U.S. Cl. CPC C30B 29/403; C30B 25/183; C30B 25/186

(57) ABSTRACT

To stably obtain a nitride crystal substrate containing AlGaN. This nitride crystal substrate includes crystal represented by a composition formula of AlₓGa₁₋ₓN. An Al composition ratio x in the composition formula is more than 0 and 1 or less, and the Al composition ratio x periodically changes in a thickness direction of the nitride crystal substrate.

### FIELD AND BACKGROUND OF THE INVENTION

The present disclosure relates to a nitride crystal substrate and a production method for the nitride crystal substrate.

Various production methods for obtaining nitride crystal substrates including group III nitride crystal have been disclosed (see, for example, Japanese Patent Laid Open Publication No. 2003-178984, and ECS Journal of Solid State Science and Technology 10 (3), 035001, 2021).

### SUMMARY OF THE INVENTION

The present disclosure has an objective to stably obtain a nitride crystal substrate containing AlGaN.

According to an aspect of the present disclosure, there is provided a nitride crystal substrate including crystal represented by a composition formula of AlₓGa₁₋ₓN, wherein
an Al composition ratio x in the composition formula is more than 0 and 1 or less, and
the Al composition ratio x periodically changes in a thickness direction of the nitride crystal substrate.

According to another aspect of the present disclosure, there is provided a production method for a nitride crystal substrate, the method including:
(a) preparing a base substrate;
(b) forming an intermediate layer above the base substrate, the intermediate layer including n-type group III nitride crystal;
(c) forming a cover layer on the intermediate layer, the cover layer including group III nitride crystal having a carrier concentration lower than a carrier concentration of the intermediate layer;
(d) making the intermediate layer porous through dislocations in the cover layer by performing electrochemical treatment, while maintaining a surface condition of the cover layer;
(e) epitaxially growing a regrowth layer on the cover layer, the regrowth layer including group III nitride crystal; and
(f) peeling off the regrowth layer from the substrate by using, as a boundary, at least a portion of the intermediate layer made porous, wherein
in (e),
crystal represented by a composition formula of AlₓGa₁₋ₓN is grown as the regrowth layer, an Al composition ratio x in the composition formula being more than 0 and 1 or less, and
the Al composition ratio x is periodically changed in a thickness direction of the regrowth layer.

According to the present disclosure, a nitride crystal substrate containing AlGaN can be obtained stably.

### BRIEF DESCRIPTION OF THE DRAWINGS

FIG. 1 is a flowchart illustrating a production method for a nitride crystal substrate according to an embodiment of the present disclosure.

FIG. 2A is a schematic cross-sectional view illustrating the production method for a nitride crystal substrate according to an embodiment of the present disclosure.

FIG. 2B is a schematic cross-sectional view illustrating the production method for a nitride crystal substrate according to an embodiment of the present disclosure.

FIG. 3A is a schematic cross-sectional view illustrating the production method for a nitride crystal substrate according to an embodiment of the present disclosure.

FIG. 3B is a schematic cross-sectional view illustrating the production method for a nitride crystal substrate according to an embodiment of the present disclosure.

FIG. 4 is a schematic cross-sectional view illustrating the production method for a nitride crystal substrate according to an embodiment of the present disclosure.

FIG. 5 is a diagram illustrating changes in the temperature in a regrowth step according to an embodiment of the present disclosure.

FIG. 6 is a schematic cross-sectional view illustrating the production method for a nitride crystal substrate according to an embodiment of the present disclosure.

FIG. 7 is a schematic cross-sectional view illustrating the production method for a nitride crystal substrate according to an embodiment of the present disclosure.

FIG. 8 is a diagram illustrating an Al flow ratio in a regrowth step according to an embodiment of the present disclosure.

FIG. 9 is a schematic cross-sectional view illustrating the production method for a nitride crystal substrate according to an embodiment of the present disclosure.

FIG. 10 is a schematic cross-sectional view illustrating the production method for a nitride crystal substrate according to an embodiment of the present disclosure.

FIG. 11A is a plan view illustrating a nitride crystal substrate according to an embodiment of the present disclosure.

FIG. 11B is a cross-sectional view illustrating the nitride crystal substrate according to an embodiment of the present disclosure.

FIG. 12 is a diagram illustrating distribution of Al composition ratio x in a thickness direction of a nitride crystal substrate according to an embodiment of the present disclosure.

FIG. 13 is a diagram illustrating a diffraction pattern obtained by an X-ray diffraction 2θ-ω scan measurement on a nitride crystal substrate according to an embodiment of the present disclosure.

FIG. 14A is a diagram illustrating an Al flow ratio in a regrowth step according to Modification Example 5.

FIG. 14B is a diagram illustrating distribution of Al composition ratio x in a thickness direction of a nitride crystal substrate according to Modification Example 5.

### DETAILED DESCRIPTION

### <Findings Obtained by Inventors>

Light-emitting diodes (LEDs) and laser diodes (LDs) with wavelengths ranging from 365 nm to about 530 nm (green) are achieved by using a substrate including gallium nitride (GaN) crystal (hereafter also referred to as a GaN crystal substrate).

On the other hand, for ultraviolet LEDs and ultraviolet LDs with wavelengths shorter than 365 nm, it is necessary to grow a layer including aluminum gallium nitride (AlGaN) crystal containing aluminum (Al) (hereinafter referred to as an AlGaN layer). However, in the case of using the GaN crystal substrate described above, it is difficult to achieve a high-quality device due to a lattice mismatch between the AlGaN layer and the GaN crystal substrate. Further, an AlGaN layer may be grown on an AlN crystal substrate produced by a sublimation method such as that described in ECS Journal of Solid State Science and Technology 10 (3), 035001, 2021. In this case too, however, it is difficult to achieve a high-quality device due to a lattice mismatch between the AlGaN layer and the AlN crystal substrate. As such, there is a need for a high-quality AlGaN crystal substrate.

A GaN crystal substrate can be obtained, for example, by the void-assisted separation (VAS) method described in Japanese Patent Laid Open Publication No. 2003-178984 described above. The VAS method involves first preparing a template that includes a GaN layer with voids and a mesh-shaped titanium nitride (TiN layer) on a sapphire substrate in this order. Next, a thick GaN main growth layer is grown on the GaN layer and the TiN layer in this state. The GaN main growth layer is then peeled off from the substrate by using, as a boundary, the GaN layer with the voids. As a result, a GaN crystal substrate can be obtained from the peeled GaN main growth layer.

Alternatively, to obtain a GaN crystal substrate, a GaN main growth layer may be grown on a template where the surface of the GaN layer is covered with a mask that partially has openings.

In any of the above cases, GaN crystal grows in the shape of islands in an initial stage of growth of the GaN main growth layer. Thereafter, as thick GaN crystal is grown, the island-shaped GaN crystals gather to form the GaN main growth layer as a continuous film. In the process of allowing such island-shaped GaN crystals to gather, crystal strain introduced during the growth of the thick GaN crystal is significantly alleviated. As a result, a thick GaN main growth layer can be grown without cracks even on a substrate including a different type of material.

An aluminum nitride (AlN) crystal substrate can be obtained by the sublimation method, as described in ECS Journal of Solid State Science and Technology 10 (3), 035001, 2021, for example. In this case, an AlN layer is first grown on a heterogeneous substrate such as a silicon carbide (SiC) substrate, in the initial stage. Next, by using this AlN layer as a seed crystal, the AlN layer is thickened by the sublimation method. An AlN crystal substrate is then obtained by peeling off the heterogeneous substrate from the AlN layer. Once the AlN crystal substrate is obtained, the AlN layer is grown again by the sublimation method with this AlN crystal substrate as the seed crystal, thereby producing an AlN ingot. Thereafter, an AlN crystal substrate is obtained by slicing the AlN ingot.

A method of obtaining an AlGaN crystal substrate is more difficult to implement than a method of obtaining a GaN or AlN crystal substrate. First, it is extremely difficult to obtain AlGaN crystal with a desired Al composition by the sublimation method because the vapor pressures of Al and Ga are different from each other. Thus, a practical method involves growing an AlGaN main growth layer on a template, as in the VAS method described above. However, in that case, Al atoms are extremely difficult to move on a growth surface, making it hard to achieve the growth process including the island-shaped growth, gathering of island-shaped crystals, and flattening of a crystal, as in the case of GaN.

In particular, during the three-dimensional growth of island-shaped AlGaN crystal, the movement of Al atoms is reduced as described above, which forms some areas with a high Al composition ratio and other areas with a low Al composition ratio in the plane. Thus, crystal strain tends to occur in the AlGaN main growth layer. As a result, in some cases, cracks may occur in the AlGaN main growth layer.

Therefore, to obtain an AlGaN crystal substrate from an AlGaN main growth layer, there is a proposed method that involves first growing a GaN layer thickly to thereby flatten the surface of the GaN layer, followed by the growth of a thick AlGaN main growth layer. However, even with this method, it is difficult to obtain an AlGaN main growth layer without cracks due to the lattice mismatch between the GaN layer and the AlGaN main growth layer.

Under such circumstances, the inventors have examined the following method as a production method for an AlGaN crystal substrate. First, an intermediate layer and a cover layer, both containing group III nitride crystal, were grown on a base substrate in this order, and electrochemical treatment was then performed on this stack. Thus, a seed substrate in which the intermediate layer is made porous while maintaining the flatness of the cover layer was fabricated. Next, by using this seed substrate, a regrowth layer including AlGaN crystal was grown on the flat cover layer as a continuous film. At this time, the Al composition ratio was periodically changed in a thickness direction of the regrowth layer. With such a method, the inventors could solve the above-described problem and succeeded in obtaining an AlGaN crystal substrate without cracks from the regrowth layer.

The present disclosure below is based on the above findings obtained by the inventors.

### Details of Embodiment of Present Disclosure

Next, an embodiment of the present disclosure will be described with reference to the accompanying drawings. The present disclosure is not limited to the following examples, but is indicated by the claims and intended to include all changes within the meaning and scope of the claims and equivalents thereof.

### Embodiment of Present Disclosure

An embodiment of the present disclosure will be described below with reference to the drawings.

### (1) Production Method for Nitride Crystal Substrate

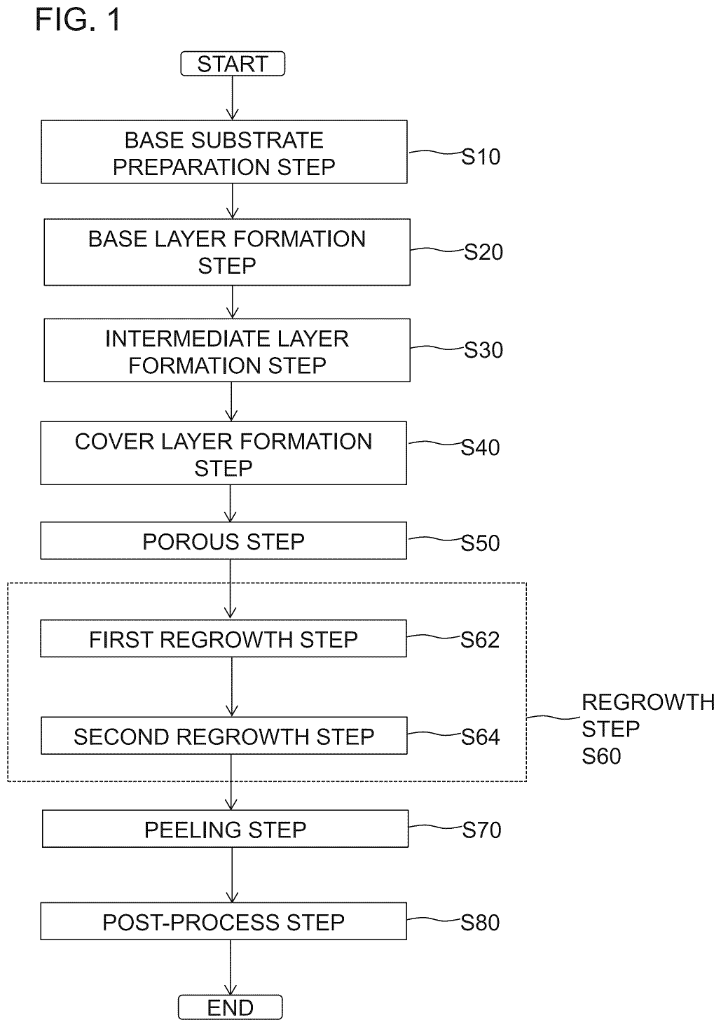

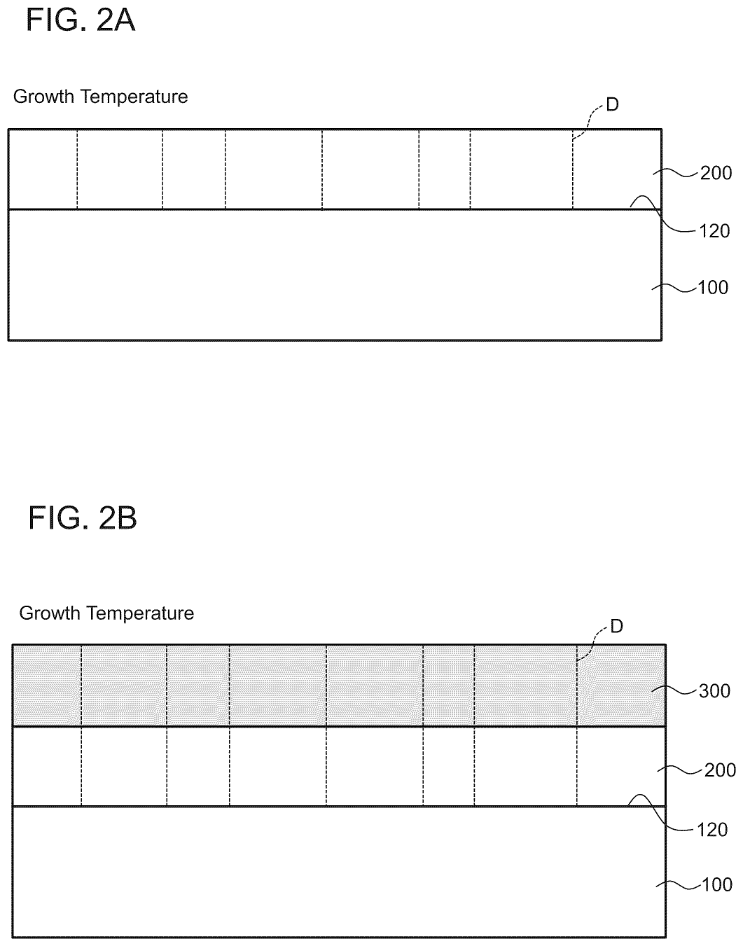

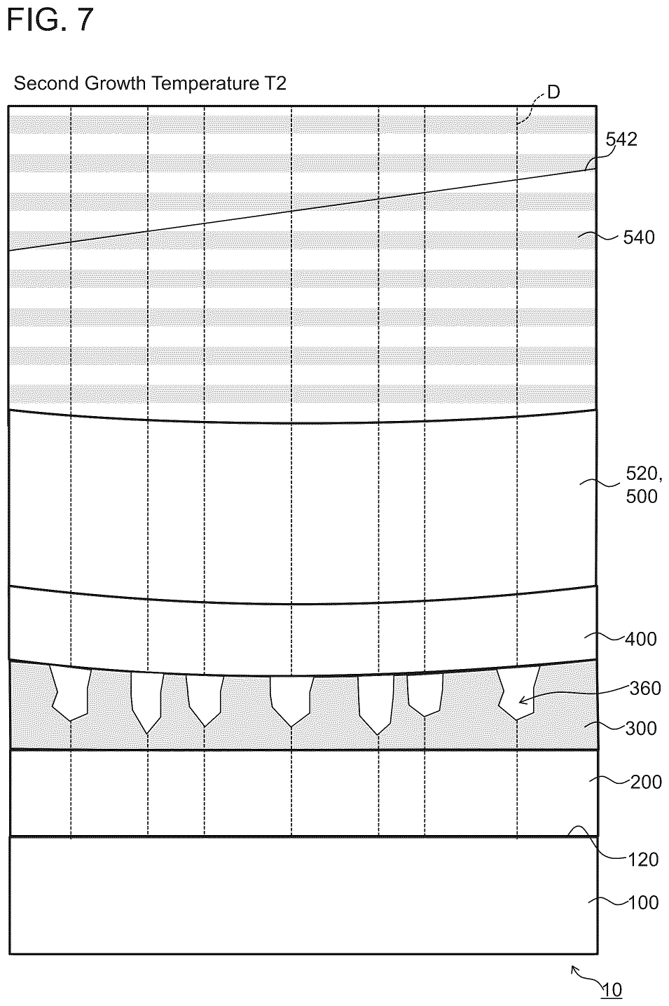

Referring to FIGS. 1 to 10, the production method for a nitride crystal substrate according to the present embodiment is described. In FIGS. 2A to 4, 6, 7, 9, and 10, hatching for some cross-sections is omitted. In FIGS. 7, 9, and 10, as described later, the grey-colored portions in second regrowth layers 540 represent regions where an Al composition ratio x is relatively large.

In the following, in group III nitride crystal with a wurtzite structure, a <0001> axis (e.g., [0001] axis) is referred to as a “c-axis”, and a (0001) plane as a “c-plane”. The (0001) plane is sometimes referred to as a “+c-plane (group III element polar plane)”, and the (000-1) plane as a “-c-plane (nitrogen (N) polar plane)”. A <1-100> axis is referred to as an “m axis”, and a <11-20> axis as an “a-axis”. The term “carrier concentration” in the present disclosure means a free carrier concentration at room temperature (22° C.). The term “creepage direction” in the present disclosure means a direction along a surface.

As illustrated in FIG. 1, the production method for a nitride crystal substrate according to the present embodiment includes, for example, a base substrate preparation step S10, a base layer formation step S20, an intermediate layer formation step S30, a cover layer formation step S40, a porous step S50, a regrowth step S60, a peeling step S70, and a post-process step S80.

### (S10: Base Substrate Preparation Step)

First, as illustrated in FIG. 2A, the base substrate 100 is prepared.

In the present embodiment, the base substrate 100 including, for example, a material different from group III nitride is prepared. Specifically, the base substrate 100 is, for example, a sapphire substrate, a SiC substrate, a silicon (Si) substrate, or a gallium arsenide (GaAs) substrate. The base substrate 100 may be insulating or conductive. Here, the base substrate 100 is, for example, a sapphire substrate.

The diameter of the base substrate 100 is, for example, 1 inch (25 mm) or more, or may be 2 inches (50 mm) or more, or 4 inches (100 mm) or more. This allows for the growth of a regrowth layer 500 with a large area, described later.

The base substrate 100 has a thickness of, for example, 150 m or more and 3 mm or less.

The base substrate 100 has a main surface 120, which becomes the growth surface, for example. In a case where the base substrate 100 is a sapphire substrate or SiC substrate, a crystal plane with a low index closest to that of the main surface 120 is, for example, the c-plane (+c-plane). In a case where the base substrate 100 is a Si substrate or GaAs substrate, a crystal plane with the low index closest to that of the main surface 120 is, for example, (001) or (111).

In the present embodiment, the c-plane of the base substrate 100 may be inclined with respect to the main surface 120. That is, the c-axis of the base substrate 100 may be inclined at a predetermined off-angle with respect to the normal of the main surface 120. The off-angle of the base substrate 100 is, for example, 0° or more and 5° or less.

The main surface 120 of the base substrate 100 has an arithmetic mean roughness (Ra) of, for example, less than 0.3 nm.

### (S20: Base Layer Formation Step)

After preparing the base substrate 100, a base layer 200 including group III nitride crystal is formed (the base layer 200 including group III nitride crystal is formed) on the base substrate 100, for example, by a vapor phase growth method, as illustrated in FIG. 2A.

Specifically, an aluminum nitride (AlN) buffer layer is grown by supplying aluminum chloride (AlCl₃) gas and ammonia (NH₃) gas to the base substrate 100 heated to a predetermined growth temperature, for example, using a hydride vapor phase epitaxy (HVPE) method. Next, a gallium nitride (GaN) layer is grown by supplying gallium chloride (GaCl) gas and NH₃ gas to the base substrate 100 heated to the predetermined growth temperature. The growth temperature of each layer is, for example, 900° C. or higher and 1100° C. or lower. In the way above, the AlN buffer layer and the GaN layer are formed as the base layer 200 on the main surface 120 of the base substrate 100 in this order. However, the base layer 200 may not have an AlN buffer layer.

In the present embodiment, the base layer 200 is of, for example, n-type. Specifically, when growing the GaN layer as the base layer 200, dichlorosilane (SiH₂Cl₂) gas is further supplied as an n-type dopant gas to grow a Si-doped GaN layer.

In the present embodiment, a carrier concentration in the GaN layer of the base layer 200 is lower than, for example, a carrier concentration in the intermediate layer 300. In other words, an n-type impurity concentration in the GaN layer of the base layer 200 is lower than, for example, an n-type impurity concentration in the intermediate layer 300. Specifically, the carrier concentration (and n-type impurity concentration) in the base layer 200 is, for example, 2×10¹⁸ cm⁻³ or less, or 1×10¹⁸ cm⁻³ or less. Thus, in the porous step S50 of making the intermediate layer 300 porous by performing the electrochemical treatment as described later, the base layer 200 can function as an etching stopper located on the lower side of the intermediate layer 300.

The lower limit of the carrier concentration in the GaN layer of the base layer 200 is not limited. However, the carrier concentration in the GaN layer of the base layer 200 may be, for example, 1×10¹⁶ cm⁻³ or more. Thus, since the base layer 200 itself has some conductivity, the etching of the intermediate layer 300 can progress toward a lower portion of the intermediate layer 300 through the electrochemical treatment during the porous step S50 described later.

The thickness of the base layer 200 is not particularly limited. However, the thickness of the base layer 200 may be, for example, more than 0 nm and 5 μm or less. By setting the thickness of the base layer 200 to 5 μm or less, the total thickness of the laminated layers on the base substrate 100 can be adjusted to, for example, 15 μm or less. This can suppress cracking that would be caused by a difference in linear expansion coefficient between respective layers, including the base substrate 100 and the base layer 200.

In the present embodiment, the crystal plane with the low index closest to the surface of the base layer 200 is the c-plane of the GaN layer. By forming a flat surface of the base layer 200 with this crystal plane in advance, the intermediate layer 300 and a cover layer 400, both having good crystallinity, can be grown on the surface of the base layer 200.

### (S30: Intermediate Layer Formation Step)

After the base layer 200 is formed, the intermediate layer 300 including n-type group III nitride crystal is formed on the base layer 200 located above the base substrate 100, for example, by the vapor phase growth method, as illustrated in FIG. 2B. (In this step, the intermediate layer 300 including group III nitride crystal in a state that does not contain any voids is formed.)

Specifically, a Si-doped GaN layer is grown as the intermediate layer 300 on the base layer 200 using, for example, the HVPE method by supplying GaCl gas, NH₃ gas, and SiH₂Cl₂ gas as n-type dopant gas to the base substrate 100 heated to the predetermined growth temperature. The intermediate layer 300 is grown with the +c-plane as the growth surface.

In the present embodiment, the carrier concentration in the intermediate layer 300 is higher than, for example, each of the carrier concentrations in the base layer 200 and in the cover layer 400. In other words, the n-type impurity concentration in the intermediate layer 300 is higher than, for example, each of the n-type impurity concentration in the base layer 200 and the n-type impurity concentration in the cover layer 400. Specifically, the carrier concentration (and n-type impurity concentration) in the intermediate layer 300 is, for example, 3×10¹⁸ cm⁻³ or more, or may be 1×10¹⁹ cm⁻³ or more. Thus, in the porous step S50 described later, the intermediate layer 300 can be selectively made porous.

The upper limit of the carrier concentration in the intermediate layer 300 is not limited. However, the carrier concentration in the intermediate layer 300 may be, for example, 1×10²⁰ cm⁻³ or less, or 5×10¹⁹ cm⁻³ or less. This can suppress the degradation of the crystallinity of the intermediate layer 300.

In the present embodiment, the thickness of the intermediate layer 300 is, for example, more than 100 nm, or may be 500 nm or more, or 1 μm or more. This allows large voids to be formed in the intermediate layer 300 in the porous step S50 described later. Thus, in the regrowth step S60 described later, voids 360 in the intermediate layer 300 can be maintained. As a result, in the peeling step S70 described later, the regrowth layer 500 can be easily and stably peeled off from the base substrate 100 by using, as the boundary, at least a portion of the intermediate layer 300 maintained in a porous state.

The upper limit of the thickness of the intermediate layer 300 is not limited. However, the thickness of the intermediate layer 300 may be 10 μm or less. By setting the thickness of the intermediate layer 300 to 10 μm or less, the total thickness of the laminated layers on the base substrate 100 can be adjusted to 15 μm or less, for example. This can suppress cracking that would be caused by a difference in linear expansion coefficient between respective layers, including the base substrate 100 and the intermediate layer 300.

### (S40: Cover Layer Formation Step)

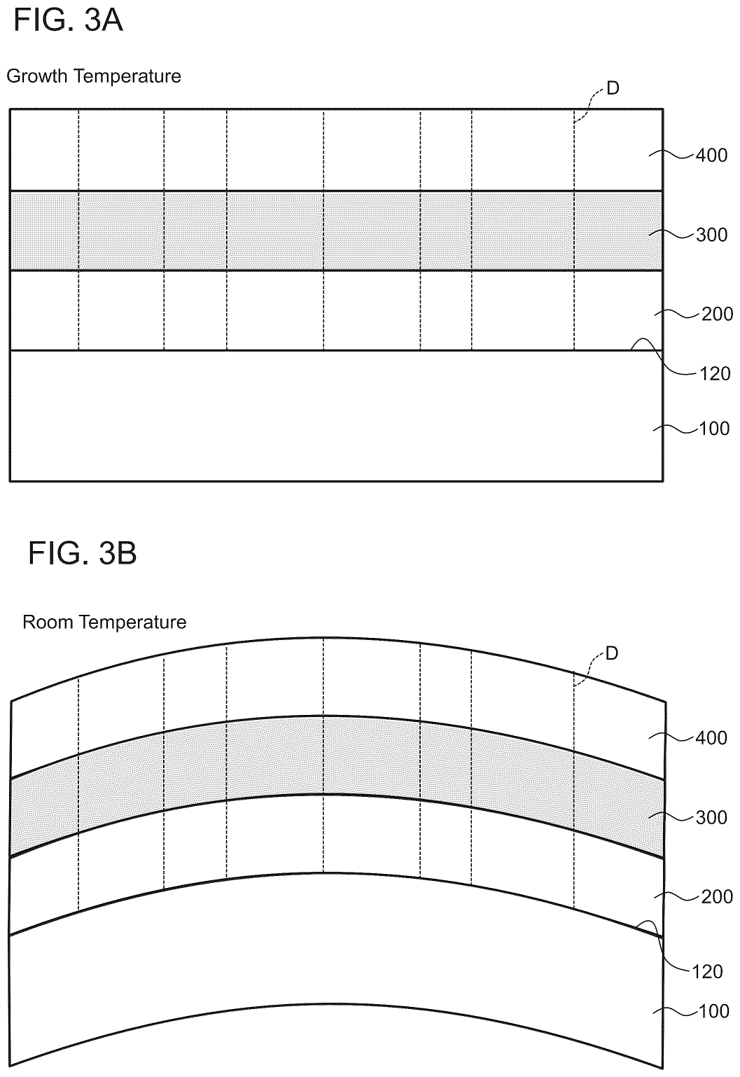

After forming the intermediate layer 300, the cover layer 400 including group III nitride crystal is formed (the cover layer 400 comprising group III nitride crystal is formed) on the intermediate layer 300, for example, by the vapor phase growth method, as illustrated in FIG. 3A.

In the present embodiment, for example, GaN crystal is grown as the cover layer 400. Thus, the crystal growth of the cover layer 400 can be easily controlled by the vapor phase growth method. As a result, the crystallinity of the cover layer 400 can be stably improved. Furthermore, the carrier concentration of the cover layer 400 can be easily controlled.

Specifically, a Si-doped GaN layer is grown as the cover layer 400 on the intermediate layer 300, for example, by the HVPE method under similar conditions as those in the intermediate layer formation step S30, except that an amount of SiH₂Cl₂ gas supplied as the n-type dopant gas is less than that in the intermediate layer formation step S30. The cover layer 400 is grown with the +c-plane as the growth surface.

In the present embodiment, the carrier concentration in the cover layer 400 is lower than, for example, the carrier concentration in the intermediate layer 300. In other words, the n-type impurity concentration in the cover layer 400 is lower than, for example, the n-type impurity concentration in the intermediate layer 300. Specifically, the carrier concentration (and n-type impurity concentration) in the cover layer 400 is, for example, 1×10¹⁸ cm⁻³ or less. Thus, in the porous step S50 described later, the intermediate layer 300 can be selectively made porous while suppressing etching of the cover layer 400. That is, under a predetermined voltage, the size of the micro-voids in the cover layer 400 can be prevented from increasing, whereas the size of the voids 360 in the intermediate layer 300 increases.

The lower limit of the carrier concentration in the cover layer 400 is not limited. However, the carrier concentration in the cover layer 400 may be, for example, 1×10¹⁶ cm⁻³ or more, or 1×10¹⁷ cm⁻³ or more. In this way, since the cover layer 400 itself has conductivity, the intermediate layer 300 can be connected to an anode 842 via the cover layer 400, so that the entire intermediate layer 300 can be equipotential with the anode 842 during the electrochemical treatment performed in the porous step S50 of making the intermediate layer 300 porous.

Here, in a state where the cover layer formation step S40 is completed, the base layer 200, the intermediate layer 300, and the cover layer 400 have a plurality of dislocations D passing therethrough in the thickness direction, for example. A dislocation density on the surface of the cover layer 400 is, for example, 1×10⁸ cm⁻² or more and 1×10⁹ cm⁻² or less. The dislocations D in the cover layer 400 are used in the porous step S50 below.

In the present embodiment, the thickness of the cover layer 400 is, for example, 10 nm or more and 2 μm or less, or may be 50 nm or more and 1.5 μm or less.

By setting the thickness of the cover layer 400 to 10 nm or more or 50 nm or more, the cover layer 400 can discharge gas generated by outgassing toward the outside of the cover layer 400 through the dislocations D of the cover layer 400 while maintaining the cover layer 400 itself, even when the outgassing of N₂ gas or the like occurs during etching of the intermediate layer 300 in the porous step S50 described later. Thus, the cover layer 400 can be prevented from being peeled off from the intermediate layer 300.

On the other hand, by setting the thickness of the cover layer 400 to 2 μm or less or 1.5 μm or less, the electrolyte is allowed to stably reach the intermediate layer 300 through the dislocations D of the cover layer 400 in the porous step S50 described later. Thus, the voids can be formed stably in the intermediate layer 300.

After growing the cover layer 400, the temperature of the base substrate 100 is decreased from the growth temperature of group III nitride crystal to room temperature. Thus, a laminated body including the base substrate 100, the base layer 200, the intermediate layer 300, and the cover layer 400 is formed.

At this time, the entire laminated body is warped due to a difference in linear expansion coefficient between the base substrate 100 and the group III nitride crystal layers including the base layer 200, the intermediate layer 300, and the cover layer 400, as illustrated in FIG. 3B. Specifically, since the linear expansion coefficient of sapphire as the base substrate 100 is greater than that of a group III nitride, the entire laminated body is warped such that the surface of the cover layer 400 becomes convex.

The base layer formation step S20, the intermediate layer formation step S30, and the cover layer formation step S40 described above are continuously performed in the same chamber without exposing the base substrate 100 to the atmosphere. This can suppress unintentional incorporation of at least one of oxygen (O) and silicon (Si) as an n-type impurity at the interfaces between the base layer 200 and the intermediate layer 300 and between the intermediate layer 300 and the cover layer 400. As a result, the effect on the carrier concentration in these layers can be suppressed.

### (S50: Porous Step)

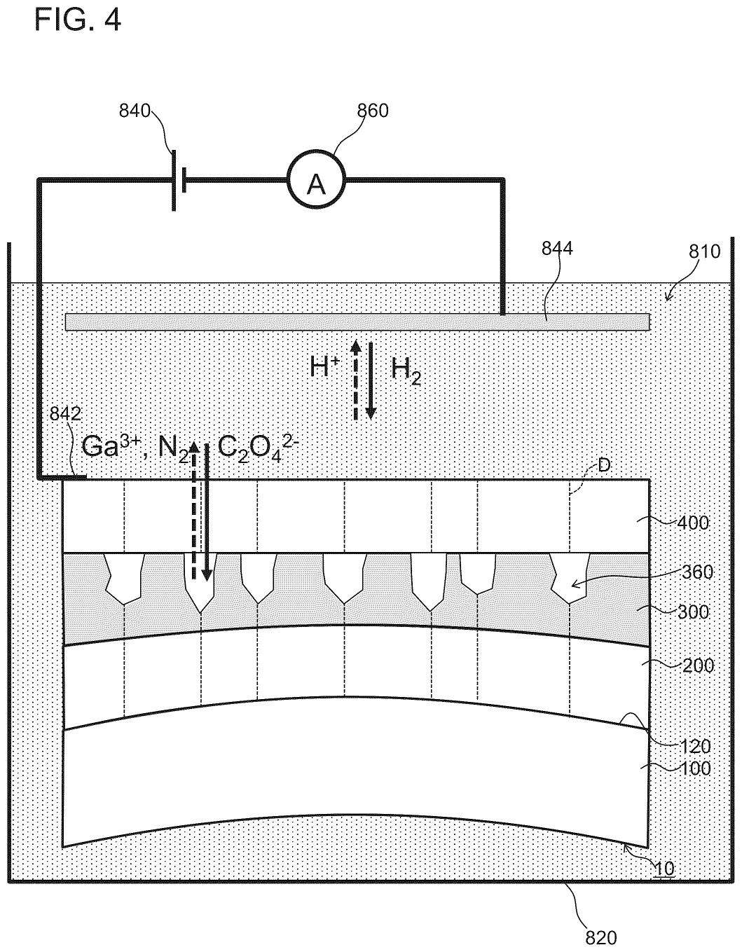

After forming the cover layer 400, as illustrated in FIG. 4, the intermediate layer 300 is made porous through the dislocations D in the cover layer 400 by performing the electrochemical treatment while maintaining the surface condition of the cover layer 400.

Specifically, the electrochemical treatment is performed, for example, by the following procedure.

As illustrated in FIG. 4, first, a process tank 820, a power source 840, and a current meter 860 are prepared. The power source 840 and the current meter 860 may be incorporated into one device as a current-voltage power source.

The process tank 820 is filled with an electrolyte 810. The electrolyte 810 is a solution containing ions capable of electrochemically etching a group III nitride. Examples of the electrolyte 810 include aqueous solutions containing oxalic acid, nitric acid, hydrofluoric acid, sulfuric acid, sodium sulfate (Na₂SO₄), sodium chloride (NaCl), sodium hydroxide (NaOH), and the like. Here, the electrolyte 810 is assumed to be an oxalic acid solution.

Furthermore, electrodes for performing the electrochemical treatment are prepared. Specifically, in a laminated body obtained after the completion of the above cover layer formation step S40, the anode 842 is provided on the surface of the cover layer 400, and the anode 842 is connected to the power source 840. Meanwhile, a cathode 844 is prepared. The cathode 844 is connected to the power source 840. For the cathode 844, a material that is resistant to corrosion but allows current to flow easily is used. Specific examples of the material for the cathode 844 include stainless steel (SUS), platinum (Pt), gold (Au), and boron-doped diamond.

After the connection of the electrodes is completed, a laminated body with the anode 842 connected thereto and the cathode 844 are immersed into the electrolyte 810 in the process tank 820. In this state, a predetermined voltage is applied between the anode 842 and the cathode 844 by the power source 840. Thus, the electrochemical treatment is performed. At this time, the progress of the electrochemical treatment is checked based on a change in the current at the current meter 860.

At this time, by performing the electrochemical treatment, the electrolyte containing C₂O₄²⁻ is allowed to penetrate the dislocations D in the cover layer 400, which has a relatively low carrier concentration, toward the intermediate layer 300, which has a relatively high carrier concentration. That is, the dislocations D in the cover layer 400 are used as a nano-sized path through which the electrolyte penetrates. The electrolyte having reached the intermediate layer 300 in this way selectively etches the intermediate layer 300. This creates a plurality of voids 360 near the plurality of dislocations D in the intermediate layer 300. As a result, the intermediate layer 300 can be made porous.

On the other hand, according to the following reaction equation, group III element ions (Ga³⁺) and nitrogen (N₂) gas produced when etching the intermediate layer 300 are released through the dislocations D in the cover layer 400 to the outside of the cover layer 400.

2GaN+6h⁺→2Ga³⁺+N₂,

where “h+” is a positive charge.

Through the above electrochemical treatment, each of the plurality of voids 360 in the intermediate layer 300 is formed, for example, at a position overlapping each of the plurality of dislocations D in the cover layer 400 described later. The plurality of voids 360 in the intermediate layer 300 extends, for example, in the thickness direction from a bottom surface of the cover layer 400 toward the base substrate 100. However, the voids 360 do not need to reach the base layer 200.

Meanwhile, partition walls of the intermediate layer 300 other than the voids 360 connect an upper portion of the base layer 200 or a lower portion of the intermediate layer 300 with the cover layer 400. Thus, the intermediate layer 300 maintains a constant thickness even though it has the plurality of voids 360.

At this time, in the present embodiment, the length of each of the plurality of voids 360 in the intermediate layer 300 in the direction along the main surface 120 of the base substrate 100 is, for example, 30 nm or more, or may be 100 nm or more, when viewed in any cross section orthogonal to the main surface 120 of the base substrate 100. Thus, in the regrowth step S60 described later, the voids 360 in the intermediate layer 300 can be maintained. As a result, in the peeling step S70 described later, the regrowth layer 500 can be easily and stably peeled off from the base substrate 100 by using, as the boundary, at least a portion of the intermediate layer 300 maintained in a porous state.

The upper limit of the length of each of the voids 360 in the intermediate layer 300 in the direction along the main surface 120 of the base substrate 100 is not limited. However, the length of each of the voids 360 in the direction along the main surface 120 of the base substrate 100 may be 10 μm or less. Thus, by adjusting conditions for the electrochemical treatment appropriately in the porous step S50, the cover layer 400 can be prevented from being peeled off due to outgassing that occurs when etching the intermediate layer 300.

At this time, in the present embodiment, the depth of each of the plurality of voids 360 in the thickness direction of the intermediate layer 300 is, for example, more than 100 nm, or 500 nm or more, or may be 1 μm or more. Also, with this configuration, in the regrowth step S60 described later, the voids 360 in the intermediate layer 300 can be maintained. As a result, in the peeling step S70 described later, the regrowth layer 500 can be easily and stably peeled off from the base substrate 100.

The upper limit of the depth of each of the voids 360 is not limited. However, the depth of the void 360 may be less than or equal to the thickness of the intermediate layer 300. Thus, in the peeling step S70 described later, excessive spread of the peeling from the intermediate layer 300 to other layers can be suppressed.

Meanwhile, in the electrochemical treatment, almost no etching occurs on the surface of the cover layer 400 having a relatively low carrier concentration. In other words, even when the cover layer 400 has the plurality of dislocations D as described above, excessive etching does not occur on the surface of the cover layer 400 near the dislocations D. Consequently, the surface condition of the cover layer 400 can be maintained flat.

At this time, in the present embodiment, after the porous step S50, the arithmetic mean roughness (Ra) of the surface of the cover layer 400 is, for example, 1.0 nm or less, and the root mean square roughness (RMS) of the surface of the cover layer 400 is, for example, 2.0 nm or less. Alternatively, the Ra of the surface of the cover layer 400 may be, for example, 0.5 nm or less, and the RMS of the surface of the cover layer 400 may be, for example, 1.0 nm or less. Here, Ra and RMS are the values obtained when the surface of the cover layer 400 is observed with an atomic force microscope (AFM) in a field of view of 5 μm square.

By maintaining a surface roughness of the cover layer 400 at a low level as described above, a thick regrowth layer 500 with good crystallinity can be stably grown on the cover layer 400.

The lower limits of Ra and RMS of the surface of the cover layer 400 are not limited and may be close to the Ra and RMS of the main surface 120 of the base substrate 100, respectively. Specifically, the lower limits of Ra and RMS of the surface of the cover layer 400 may be 0.1 nm and 0.2 nm, respectively.

Specific conditions for the electrochemical treatment that can implement selective etching of the intermediate layer 300 described above are, for example, as follows. A treatment voltage is adjusted based on the carrier concentration of the intermediate layer 300 or the like. A treatment current is adjusted based on a treatment area (an area of the base substrate 100). A treatment time is adjusted based on the thickness of the intermediate layer 300.

Electrolyte temperature: room temperature (10° C. or higher and 30° C. or lower)
Treatment voltage: 1 V or more and 200 V or less, or 10 V or more and 20 V or less
Treatment current: 0.01 mA or more and 60 A or less, or 0.1 mA or more and 10 A or less
Treatment time: 0.1 min or more and 180 min or less, or 1 min or more and 30 min or less

As the intermediate layer 300 is made porous through the above electrochemical treatment, the cover layer 400 and the laminated body including the base substrate 100 and the base layer 200 are separated, while the intermediate layer 300 made porous is interposed therebetween, as illustrated in FIG. 4. The presence of the voids 360 with the above-described size in the intermediate layer 300 can significantly facilitate this separation.

Thus, the warpage of the cover layer 400 in the porous step S50 can be reduced to be smaller than the warpage of the cover layer 400 before the porous step S50. That is, the cover layer 400 can be brought into a condition of being nearly flat.

Meanwhile, a seed substrate 10 is brought into a condition closer to a configuration where the group III nitride crystal layer on the base substrate 100 is thin. Thus, the warpage of the base substrate 100 in the porous step S50 can be reduced to be smaller than the warpage of the base substrate 100 before the porous step S50.

After the electrochemical treatment, the seed substrate 10 for nitride crystal growth is removed from the electrolyte in the process tank 820. Thereafter, the seed substrate 10 for nitride crystal growth that has been removed from the process tank 820 is washed with pure water or the like and dried. Consequently, the electrolyte remaining in the voids 360 of the intermediate layer 300 is removed. In the way above, the porous step S50 is completed.

In this way, the seed substrate 10 is obtained. The seed substrate 10 is used for the regrowth step S60 and the peeling step S70 described later.

### (S60: Regrowth Step)

After the porous step S50 is completed, the regrowth layer 500 including group III nitride crystal is epitaxially grown on the cover layer 400. The growing method for the regrowth layer 500 uses, for example, the vapor phase growth method.

In the present embodiment, crystal represented by the composition formula of AlₓGa₁₋ₓN, where the Al composition ratio x is more than 0 and 1 or less, is grown as the regrowth layer 500. At this time, the Al composition ratio x is periodically changed in a thickness direction of the regrowth layer 500.

In the present embodiment, by growing the regrowth layer 500 including the above-described AlGaN crystal on the flat cover layer 400 provided on the porous intermediate layer 300, the crystal strain to be generated in a creepage direction of the regrowth layer 500 can be alleviated more than in a case where the porous step S50 is not performed.

Further, in the present embodiment, periodically changing the Al composition ratio x in the thickness direction of the regrowth layer 500 enables to stably alleviate the crystal strain to be generated in a creepage direction of the regrowth layer 500.

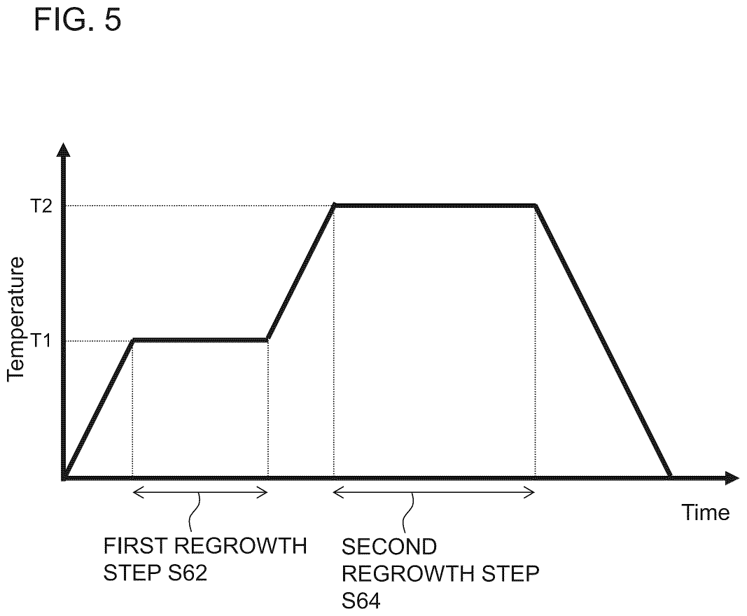

As illustrated in FIG. 5, in the regrowth step S60 of the present embodiment, the growth temperature may be adjusted in two stages. Specifically, the regrowth step S60 may have, for example, a first regrowth step S62 and a second regrowth step S64.

In this case, in the regrowth step S60, first, the temperature of the seed substrate 10 is increased from room temperature to a first growth temperature T1, as illustrated in FIG. 5.

### (S62: First Regrowth Step)

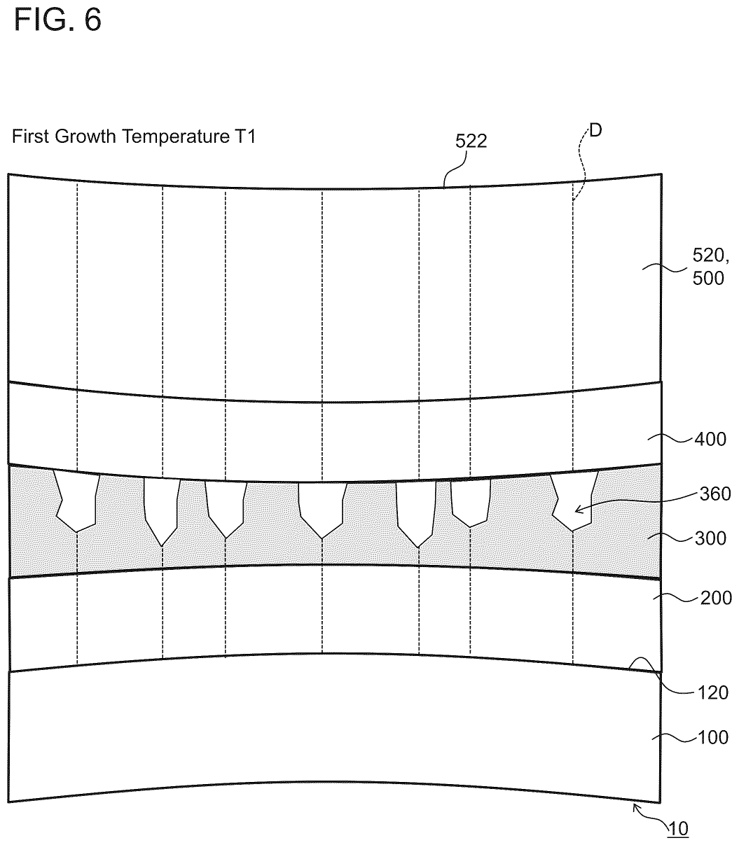

When the temperature of the seed substrate 10 reaches the first growth temperature T1, a first regrowth layer 520 is grown on the cover layer 400 at this first growth temperature T1, as illustrated in FIG. 6.

Specifically, an AlGaN layer is grown by supplying AlCl₃ gas, GaCl gas and NH₃ gas to the seed substrate 10 heated to the first growth temperature T1, for example, using the HVPE method. In the way above, the AlGaN layer is epitaxially grown on the surface of the cover layer 400 as the first regrowth layer 520. Various dopants may be added to the AlGaN layer as the first regrowth layer 520.

At this time, in the present embodiment, the first growth temperature T1 of the first regrowth step S62 is set lower than a second growth temperature T2 of the second regrowth step S64 as a main growth described later. That is, the first growth temperature T1 of the first regrowth step S62 is set slightly lower than the growth temperature of typical group III nitride crystal.

At this time, the base substrate 100 is elongated as the temperature increases from room temperature to the first growth temperature T1. However, since the first growth temperature T1 is lower (than the growth temperature of the base layer 200 and the like), the base substrate 100 does not become completely flat, with the main surface 120 of the base substrate 100 remaining slightly convex.

In contrast, since the linear expansion coefficient of the cover layer 400 is smaller than that of the base substrate 100, the elongation of the cover layer 400 is smaller than that of the base substrate 100. Consequently, the cover layer is warped such that the surface of the cover layer 400 is recessed. However, by making the first growth temperature T1 lower, excessive warpage of the cover layer 400 can be suppressed. Thus, the occurrence of cracks in the cover layer 400 can be suppressed. As a result, the occurrence of cracks in the regrowth layer 500 on the cover layer 400 can also be suppressed.

At this time, in the present embodiment, the first growth temperature T1 is set to 970° C. or lower, for example. This can stably suppress the occurrence of cracks in the cover layer 400 in the first regrowth step S62. As a result, the occurrence of cracks in the regrowth layer 500 on the cover layer 400 can be stably suppressed.

On the other hand, the first growth temperature T1 may be set to 800° C. or higher, for example. Thus, the group III nitride crystal can be stably grown as the first regrowth layer 520.

By adjusting the first growth temperature T1 as described above, the first regrowth layer 520 with a predetermined thickness can be grown on the cover layer 400 while suppressing the occurrence of cracks in the cover layer 400. Thus, the total thickness of the group III nitride crystal layers (cover layer 400 and first regrowth layer 520) above the intermediate layer 300 made porous can be stably thickened. As a result, in the second regrowth step S64 as the main growth described later, the group III nitride crystal layer above the intermediate layer 300 can be made less prone to cracking when the temperature is increased to the second growth temperature T2.

At this time, in the present embodiment, by starting the growth of the first regrowth layer 520 on the cover layer 400 with a flat surface, the regrowth layer 500 can be grown in a step-flow growth mode at least in an initial stage of the growth of the first regrowth layer 520 as the regrowth layer 500 (in a stage where the thickness thereof is thin). That is, in the initial stage of the growth, the island-shaped growth of the regrowth layer 500 including AlGaN crystal can be suppressed. Thus, the regrowth layer 500 as the continuous film including AlGaN crystal can be grown in the step-flow growth mode over the entire surface of the cover layer 400 with a c-plane 522 (+c-plane) as the growth surface. As a result, the Al composition ratio x can be made uniform in the plane of the first regrowth layer 520. Further, the crystallinity of the first regrowth layer 520 can be improved.

Thereafter, when the first regrowth layer 520 is gradually grown after the growth in the step-flow growth mode in the initial stage of the growth of the first regrowth layer 520, a tilted interface other than the c-plane may be generated in at least a portion of the first regrowth layer 520. That is, after the first regrowth layer 520 with the predetermined thickness is grown in the step-flow growth mode, the first regrowth layer 520 may be grown three-dimensionally. Thus, at least some of the plurality of dislocations D having propagated from the cover layer 400 in the direction along the c-axis of the first regrowth layer 520 can be bent and propagate toward the direction substantially perpendicular to the respective tilted interfaces at positions where the tilted interfaces are exposed. This allows at least some of the plurality of dislocations D to be locally collected. By eliminating the locally collected dislocations D, the dislocation density can be reduced. As a result, the number of pits on the surface of the regrowth layer 500 can also be reduced.

At this time, in the present embodiment, the Al composition ratio x in the first regrowth layer 520 may be made uniform across a thickness direction of the first regrowth layer 520. In this case, the Al composition ratio x in the first regrowth layer 520 may be, for example, more than 0 and 1 or less, or 0.05 or more and 0.8 or less. By setting the Al composition ratio x in the first regrowth layer 520 to 0.05 or more and 0.8 or less, appropriate crystal strain can be applied to the porous intermediate layer 300.

At this time, in the present embodiment, the thickness of the first regrowth layer 520 is, for example, 1 μm or more, or may be 10 μm or more, or 20 μm or more. Thus, in the second regrowth step S64 as the main growth described later, the group III nitride crystal layer above the intermediate layer 300 can be stably made less prone to cracking when the temperature is increased to the second growth temperature.

Meanwhile, the upper limit of the thickness of the first regrowth layer 520 is not particularly limited. However, the thickness of the first regrowth layer 520 is, for example, 300 μm or less, or may be 100 μm or less.

When the thickness of the first regrowth layer 520 reaches a predetermined thickness, the growth of the first regrowth layer 520 is terminated by stopping the supply of AlCl₃ gas and GaCl gas. However, the supply of NH₃ gas is still continued.

Thereafter, the temperature of the seed substrate 10 is increased from the first growth temperature T1 to the second growth temperature T2, as illustrated in FIG. 5.

### (S64: Second Regrowth Step)

After increasing the temperature of the seed substrate 10 from the first growth temperature T1 to the second growth temperature T2, the growth of the regrowth layer 500 is resumed as the second regrowth layer 540, as illustrated in FIG. 7. That is, at the second growth temperature T2, the thick second regrowth layer 540 is grown as the main growth on the first regrowth layer 520.

Specifically, for example, the second regrowth step S64 is performed in the same chamber as the first regrowth step S62 without atmospheric exposure. In the second regrowth step S64, an AlGaN layer is epitaxially grown as the second regrowth layer 540 on the first regrowth layer 520 by supplying AlCl₃ gas, GaCl gas and NH₃ gas to the seed substrate 10 heated to the second growth temperature T2. Various dopants may be added in the AlGaN layer as the second regrowth layer 540.

At this time in the present embodiment, as illustrated in FIG. 7, the Al composition ratio x is periodically changed in a thickness direction of the second regrowth layer 540 within a range of more than 0 and 1 or less in the Al composition ratio x. In FIG. 7, the grey-colored portions in second regrowth layers 540 represent regions where the Al composition ratio x is relatively large.

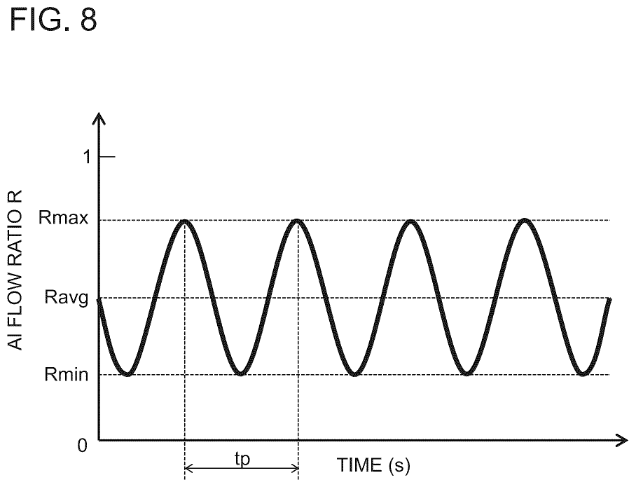

Specifically, as illustrated in FIG. 8 for example, an Al flow ratio R is changed as the second regrowth layer 540 is grown. The term “Al flow ratio R” as used herein is a ratio of a flow rate of raw material gas for Al to a total flow rate of the flow rate of the raw material gas for Al and a flow rate of raw material gas for Ga, which is determined based on the following formula (A).

$$R = [ {AlCl}_{3} ] / ( [ {AlCl}_{3} ] + [ GaCl ] ) \qquad ( A )$$

where [AlCl₃] is a flow rate of AlCl₃ gas that serves as the raw material gas for Al, and [GaCl] is a flow rate of GaCl gas that serves as the Ga raw material gas.

That is, in the second regrowth step S64,
a cycle including:
adjusting the Al flow ratio R to a minimum value Rmin;
gradually increasing the Al flow ratio R from the minimum value Rmin as the second regrowth layer 540 is grown;
adjusting the Al flow ratio R to a maximum value Rmax; and
gradually decreasing the Al flow ratio R from the maximum value Rmax as the second regrowth layer 540 is grown,
is repeated.

This way of adjusting the Al flow ratio R when growing the second regrowth layer 540 enables the Al composition ratio x to be periodically changed in the thickness direction of the second regrowth layer 540. This can cause local strain at an unbalanced degree in the thickness direction of the second regrowth layer 540, which can generate slip in an atomic plane. As a result, the crystal strain generated in a creepage direction of the second regrowth layer 540 can be stably alleviated.

At this time, in the present embodiment, an average value xavg of the Al composition ratio x in the second regrowth layer 540 is 0.05 or more and 0.8 or less. Specifically, the average value Ravg of the Al flow ratio R is adjusted to 0.05 or more and 0.8 or less such that the average value xavg of the Al composition ratio x falls within the range described above. In this way, appropriate crystal strain can be applied to the porous intermediate layer 300 based on the average value xavg of the Al composition ratio x in the second regrowth layer 540.

At this time, in the present embodiment, one period of the Al composition ratio x in the thickness direction of the second regrowth layer 540 may be 5 nm or more and 2000 nm or less, or 5 nm or more and 500 nm or less. Specifically, a period tp by which the Al flow ratio R is changed is adjusted such that the period of the Al composition ratio x falls within the range described above. In this way, the slip in the atomic plane described above can be stably generated in a portion where the Al composition ratio x changes.

At this time, in the present embodiment, a difference between a maximum value and a minimum value of the Al composition ratio x in the second regrowth layer 540 is 0.2 xavg or more and xavg or less, where xavg is the average value of the Al composition ratio x. Specifically, a difference (width of change) Rmax-Rmin between a maximum value and a minimum value of the Al flow ratio R is adjusted to 0.2 Ravg or more and Ravg or less such that the difference between the maximum value and the minimum value of the Al composition ratio x falls within the above-described range. In this way, the slip in the atomic plane described above can be stably generated.

At this time, in the present embodiment, even when the second growth temperature T2 of the second regrowth step S64 as the main growth is higher than the first growth temperature T1 of the first regrowth step S62, the group III nitride crystal layer above the intermediate layer 300 is made less prone to cracking because the total thickness of the cover layer 400 and first regrowth layer 520 as the group III nitride crystal layer above the intermediate layer 300 is set to be large, as described above. Thus, the regrowth layer 500 can be grown stably.

At this time, in the present embodiment, by setting the second growth temperature T2 of the second regrowth step S64 higher than the first growth temperature T1, the second regrowth layer 540 can be grown stably in the step-flow growth mode (grown two-dimensionally or grown in the lateral direction) with a c-plane 542 as the growth surface, as described above. Thus, the thick second regrowth layer 540 with good crystallinity can be grown while improving the surface flatness. Note that the c-axis, which is the normal of the c-plane 542 of the second regrowth layer 540, may be inclined at an off-angle that takes over the c-axis of the base substrate 100, which is inclined at a predetermined off-angle.

At this time, in the present embodiment, the second growth temperature T2 is, for example, 980° C. or higher, or may be 1000° C. or higher. Thus, the second regrowth layer 540 can be grown stably in the step-flow growth mode. As a result, the thick second regrowth layer 540 with good crystallinity can be grown stably while improving the flatness of the second regrowth layer 540.

Meanwhile, the second growth temperature T2 may be set to 1200° C. or lower, for example. This can suppress the roughening of the surface of the second regrowth layer 540 due to excessively high growth temperature.

At this time, in the case where the tilted interface is generated in at least a portion of the first regrowth layer 520 (the first regrowth layer 520 is grown three-dimensionally) in the first regrowth step S62 of the present embodiment, the second regrowth layer 540 is grown in the horizontal direction as described above, so that a tilted interface in the second regrowth layer 540 can be gradually shrunk, that is, the c-plane 542 can be gradually enlarged. Thus, the second regrowth layer 540 with the mirror-finished surface can be grown.

At this time, in the present embodiment, the total thickness of the regrowth layer 500 (the first regrowth layer 520 and the second regrowth layer 540) is, for example, 600 μm or more, and may be 1 mm or more. The upper limit of the thickness of the regrowth layer 500 is not particularly limited. However, from the viewpoint of improving productivity, the thickness of the regrowth layer 500 may be, for example, 100 mm or less.

Here, in the growth process of the thick regrowth layer 500, the dislocations D move in a random walk manner. Thus, the dislocations D are caused to gather or to form loops during the growth of the regrowth layer 500. Such a phenomenon can reduce the number of dislocations D reaching the surface of the thick second regrowth layer 540.

Alternatively, in the first regrowth step S62 of the present embodiment, in the case where the tilted interface is generated in at least a portion of the first regrowth layer 520 (the first regrowth layer 520 is grown three-dimensionally), the dislocations can be collected locally at portions where adjacent tilted interfaces gather during the process of growing the second regrowth layer 540 in the horizontal direction. Also in this case, the number of dislocations D reaching the surface of the thick second regrowth layer 540 can be reduced.

As a result, the dislocation density of the second regrowth layer 540 can be reduced. (Note that the number of dislocations in FIG. 7 is not reduced significantly for simplification of FIG. 7.)

### (S70: Peeling Step)

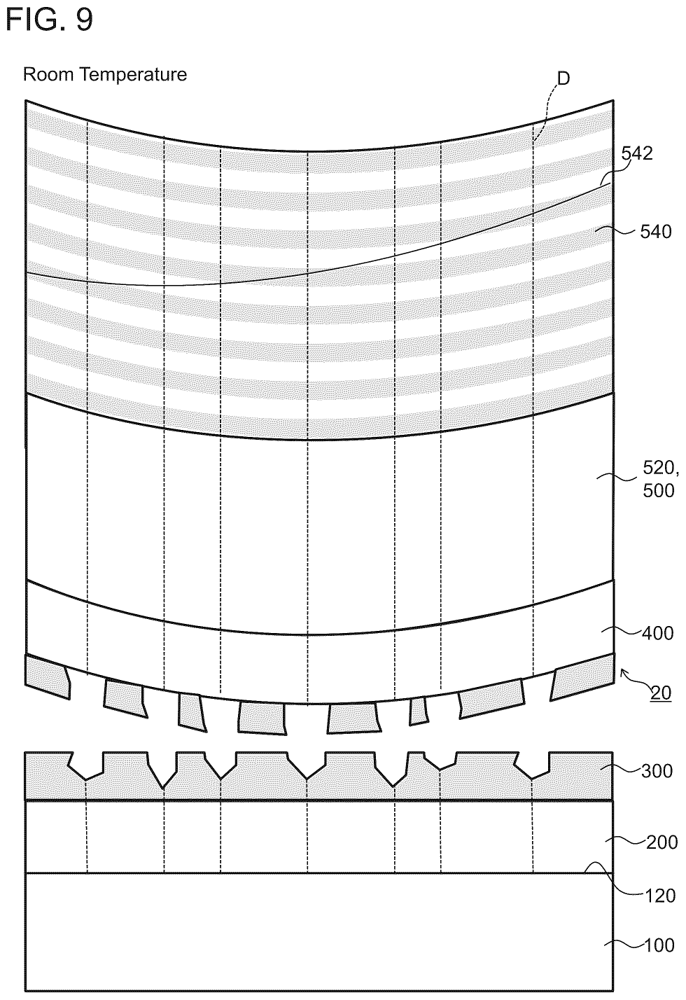

After the regrowth step S60 is completed, as illustrated in FIG. 9, the regrowth layer 500 is peeled off from the base substrate 100 by using, as the boundary, at least a portion of the intermediate layer 300 made porous.

In the present embodiment, the regrowth layer 500 is peeled off spontaneously from the base substrate 100 while decreasing the temperature after the regrowth step S60. This can eliminate the need for a special separate step of peeling. In other words, the manufacturing method can be simplified.

Here, in the regrowth step S60, tensile stress is generated in the regrowth layer 500 (in the direction along the main surface 120 of the base substrate 100). This is due to the fact that, for example, the dislocation density decreases as the thickness of the regrowth layer 500 increases, as described above.

The tensile stress generated in the regrowth layer 500 in the direction along the main surface 120 of the base substrate 100 in this way warps the c-plane 510 of the regrowth layer 500 into a spherical shape with an upper side thereof recessed. Thus, the regrowth layer 500 is peeled off spontaneously and gradually from an outer periphery of the base substrate 100 toward a center thereof. That is, by utilizing the warpage of the c-plane 510 of the regrowth layer 500, the regrowth layer 500 can be gradually peeled off from the outer periphery toward the center of the base substrate 100. In other words, the regrowth layer 500 can be peeled off evenly in a concentric manner with respect to the center of the base substrate 100. As a result, the regrowth layer 500 with a large area can be peeled off easily and stably.

By the above peeling step S70, a peeled intermediate 20 including at least the cover layer 400 and the regrowth layer 500 is formed. Residual fragments of the intermediate layer 300 may remain on the bottom surface of the cover layer 400 of the peeled intermediate 20.

### (S80: Post-Treatment Step)

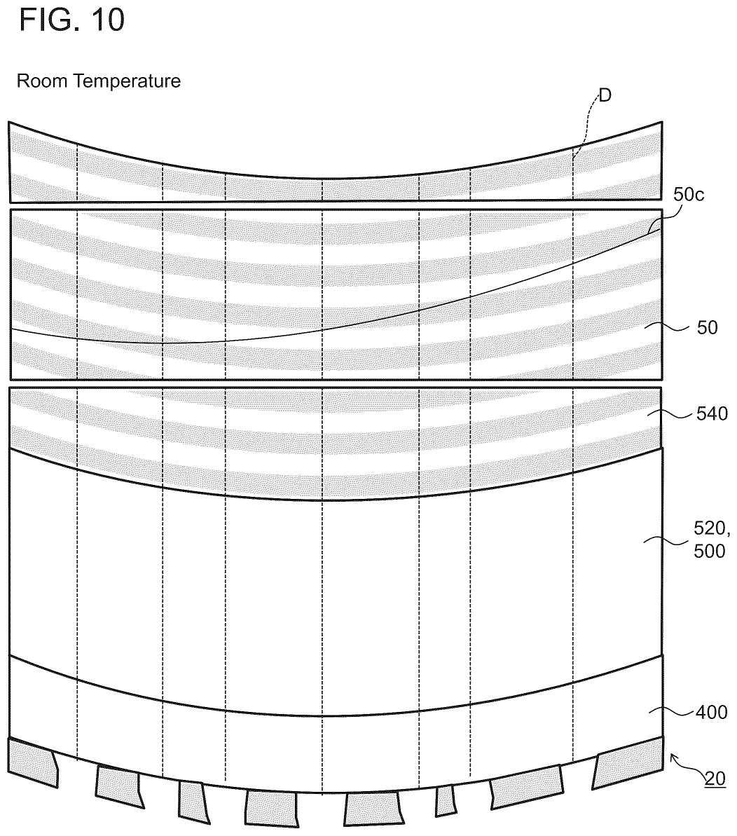

After the peeling step S70 is completed, as illustrated in FIG. 10, the regrowth layer 500 is sliced by a wire saw, for example, along a cutting plane perpendicular to the normal direction at the center of the surface of the regrowth layer 500. This forms a nitride crystal substrate 50 (which may be hereinafter abbreviated as the “substrate 50”) as an as-sliced substrate.

Next, both surfaces of the substrate 50 are polished by a polishing device. Thus, the main surface of the substrate 50 becomes mirror-finished.

Through the steps described above, the substrate 50 including the AlGaN crystal of the present embodiment is obtained.

### (Process for Fabricating Laminate or Semiconductor Device)

Thereafter, the substrate 50 described above may be used to fabricate a laminate or a semiconductor device. The laminate or the semiconductor device includes, for example, the substrate 50 described above and a semiconductor layer provided on the substrate 50 and including group III nitride crystal. This enables the production of a high-quality semiconductor device, such as an ultraviolet LED or an ultraviolet LD, for example.

### (2) Nitride Crystal Substrate

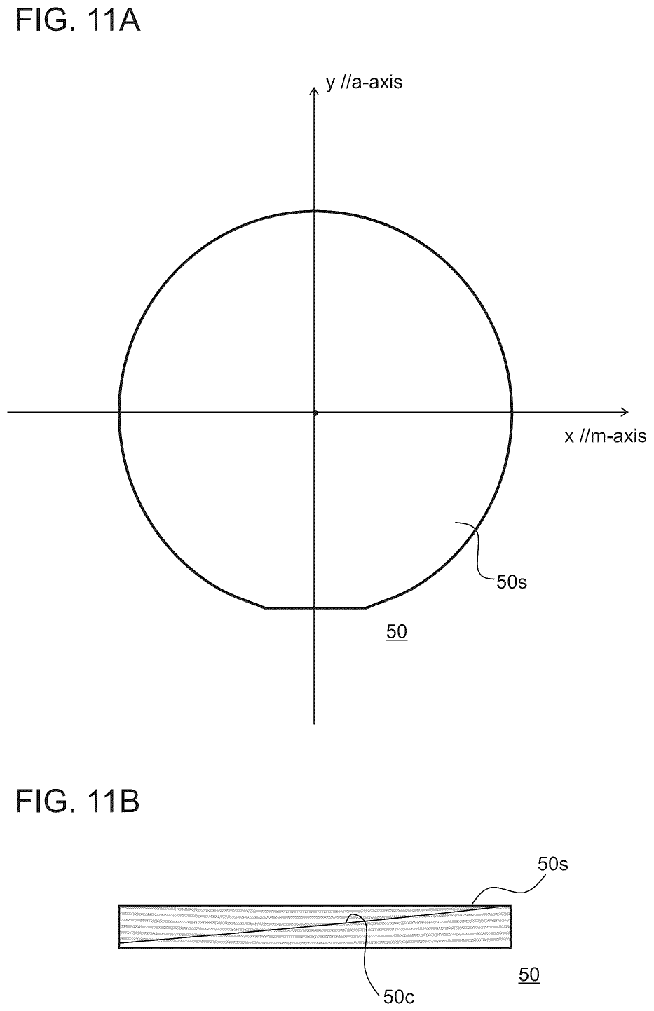

Referring to FIGS. 11A to 13, the nitride crystal substrate 50 according to the present embodiment will be described.

### (Basic Characteristics)

In the present embodiment, the substrate 50 includes crystal represented by the composition formula of AlₓGa₁₋ₓN, for example. The Al composition ratio x in the composition formula of the substrate 50 is, for example, more than 0 and 1 or less.

The diameter of the substrate 50 is, for example, 1 inch (25 mm) or more, or may be 2 inches (50 mm) or more, or 4 inches (100 mm) or more. Further, the thickness of the substrate 50 is, for example, 300 μm or more and 2 mm or less.

The substrate 50 has a main surface 50s, for example, where the closest crystal plane with a low index is a c-plane 50c. The main surface 50s of the substrate 50 is, for example, mirror-finished. Thus, the main surface 50s of the substrate 50 has a root mean square roughness RMS of, for example, less than 1 nm.

In the present embodiment, the substrate 50 does not contain, for example, any polarity reversal zones (inversion domains) because the regrowth layer 500 is grown with the c-plane as a continuous growth surface. In other words, the c-plane 50c is the closest crystal plane with a low index for the main surface 50s of the substrate 50, over the entire main surface 50s. In the present embodiment, the c-plane 50c being the closest crystal plane with a low index for the main surface 50s of the substrate 50 may be curved in a concave spherical shape with respect to the main surface 50s due to, for example, warpage caused in the peeling step S70 described above.

(Periodic structure of Al composition ratio)

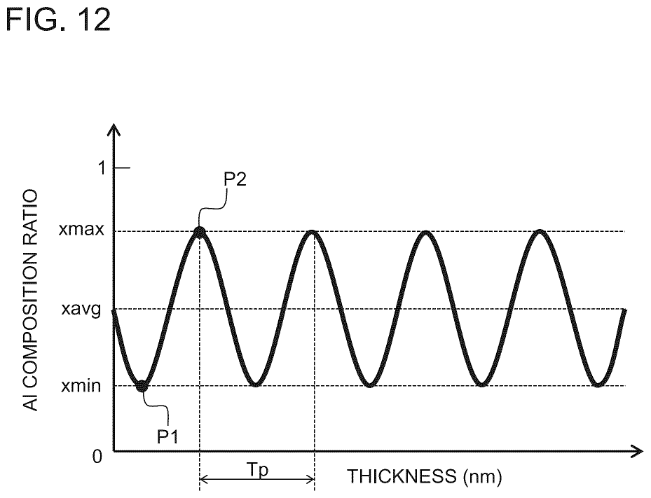

As illustrated in FIGS. 11B and 12, in the present embodiment, the Al composition ratio x in the substrate 50 periodically changes (cyclically varies) in a thickness direction of the substrate 50. In FIG. 11B, the grey-colored portions in the substrate 50 represent regions where the Al composition ratio x is relatively large.

Specifically, the Al composition ratio x in the substrate 50 is distributed in a shape of so-called sine curve in the thickness direction (depth direction) in the substrate 50, for example. In other words, the substrate 50 has, for example, minimum points P1 at which the Al composition ratio x has a minimum value xmin, and maximum points P2 at which the Al composition ratio x has a maximum value xmax, alternately in the thickness direction. The Al composition ratio x in the substrate 50 gradually increases from a minimum point P1 toward a maximum point P2 in the thickness direction of the substrate 50. On the other hand, the Al composition ratio x in the substrate 50 gradually decreases from a maximum point P2 toward a minimum point P1 in the thickness direction of the substrate 50.

It is considered that the slip in the atomic plane described above is generated due to the local strain with an unbalanced degree produced by the composition change in the substrate 50 in the thickness direction of the substrate 50. Causing the Al composition ratio x in the thickness direction of the substrate 50 to be distributed in a shape of smooth sine curve, the unbalanced strain, which generates the slip in the atomic plane, can be caused in the thickness direction of the substrate 50 without interruption. As a result, the slip in the atomic plane can be effectively generated.

In the present embodiment, the average value xavg of the Al composition ratio x in the substrate 50 is, for example, 0.05 or more and 0.8 or less.

By setting the average value xavg of the Al composition ratio x in the substrate 50 to 0.05 or more and 0.8 or less, peelability of the regrowth layer 500 using, as the boundary, the intermediate layer 300 as described above can be improved, thus allowing the substrate 50 to be stably obtained from the regrowth layer 500.

From the viewpoint of application to semiconductor devices, by setting the average value xavg of the Al composition ratio x in the substrate 50 to 0.05 or more, the UV light transmittance of the substrate 50 can be improved when the substrate 50 is applied to UV LEDs or UV LDs. On the other hand, if the average value xavg of the Al composition ratio x in the substrate 50 is more than 0.8, Al vacancies occur more frequently. Consequently, the substrate 50 is prone to lose its conductivity. In contrast, by setting the average value xavg of the Al composition ratio x in the substrate 50 to 0.8 or less, the frequency of the occurrence of Al vacancies can be suppressed. As a result, conductivity can be imparted to the substrate 50 including AlGaN crystal.

In the present embodiment, one period Tp of the Al composition ratio x in the thickness direction of the substrate 50 is, for example, 5 nm or more and 2000 nm or less, or 5 nm or more and 500 nm or less. The term “period Tp of the Al composition ratio x” as used herein means a thickness from a first maximum point P2 of the Al composition ratio x reached first in measuring the Al composition ratio x toward a thickness direction of the substrate 50 to a second maximum point P2 adjacent (reached next) to the first maximum point P2, having a minimum point P1 sandwiched between these points.

In the present embodiment, since the substrate 50 has such a period Tp of the Al composition ratio x as described above, the number of periods by which the Al composition ratio x in the substrate 50 changes is greater than the number of periods for general multi-quantum well of laser diodes. Specifically, the number of periods of the Al composition ratio x in the thickness direction of the substrate 50 may be, for example, 150 or more and 4×10⁵ or less, or 600 or more and 4×10⁵ or less.

In the present embodiment, a difference xmax-xmin between a maximum value and a minimum value of the Al composition ratio x in the substrate 50 is, for example, 0.2 xavg or more and xavg or less, where xavg is the average value of the Al composition ratio x. The term “difference xmax-xmin between the maximum value and the minimum value of the Al composition ratio x” as used herein means a width of change in which the Al composition ratio x changes. In other words, xmax-xmin is a value corresponding to amplitude, when the change in the Al composition ratio x is assumed to be “oscillation” or “wave”.

The substrate 50 may satisfy the following formulas (B) and (C), for example:

$$0.1 xavg \leq x max - x avg \leq 0.5 xavg \qquad ( B )$$

$$0.1 xavg \leq x avg - x min \leq 0.5 xavg \qquad ( C )$$

In the present embodiment, layers (homogeneous composition layers) having the same Al composition ratio x in the periodic structure for the Al composition ratio x in the substrate 50 may not be, for example, parallel to the main surface 50s of the substrate 50. Specifically, layers having the same Al composition ratio x may each have warpage in a concave spherical shape with respect to the main surface 50s of the substrate 50, in accordance with the warpage of the regrowth layer 500 in the peeling step S70 as described above. In this case, the main surface 50s of the substrate 50 may have periodic structure in which the Al composition ratio x is distributed in, for example, a concentric shape formed around a center of the main surface 50s. Alternatively, upon tilting a crystal at a time of polishing for obtaining the main surface 50s, the main surface 50s of the substrate 50 may have periodic structure in which the Al composition ratio x is distributed in, for example, a straight line (striped) shape, arc shape, or ellipse shape.

The periodic structure for Al composition ratio x in the substrate 50 as described above can be confirmed by, for example, Secondary Ion Mass Spectrometry (SIMS) and the X-ray diffraction measurement described later.

### (Structure Free of Cracks)

In the present embodiment, crystal strain generated in a creepage direction of the regrowth layer 500 including AlGaN crystal can be alleviated by applying the above-described production method, and forming the above-described periodic structure for the Al composition ratio x in the regrowth layer 500. Thus, the substrate 50 obtained from the regrowth layer 500 is free of cracks.

### (Characteristic 1 Relating to X-Ray Diffraction Measurement)

In the present embodiment, since the substrate 50 has the above-described periodic structure for the Al composition ratio x, a diffraction pattern obtained through X-ray diffraction measurement on the substrate 50 has a fringe.

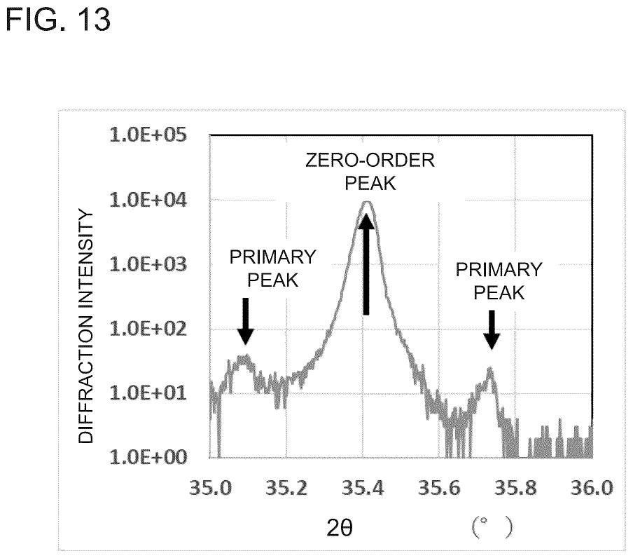

Specifically, as illustrated in FIG. 13, when using a Cu Kal line (wavelength: 0.15405 nm) to perform an X-ray diffraction 2θ-ω scan measurement on the substrate 50 under a condition under which diffraction of the (0002) plane of AlGaN is measured by symmetric reflection, a diffraction pattern obtained by the 2θ-ω scan measurement has a zero-order peak (zeroth peak), and a primary peak (first peak) as a satellite peak, for example. The zero-order peak is a peak having a highest diffraction intensity of the (0002) plane of AlGaN. The satellite peak is a peak that occurs dependent on the periodic structure of the Al composition ratio x at a position having an interval from the zero-order peak, the satellite peak also occurs with an intensity lower than the intensity of the zero-order peak.

In the present embodiment, the zero-order peak occurs within a range of 34.62° or more and 35.730 or less in a diffraction angle 2θ, for example. An average value of a lattice constant in a <0001>-axis direction of the substrate 50 is determined based on the diffraction angle 2θ of the zero-order peak. The diffraction angle 2θ of the zero-order peak being within the above-described range corresponds to the average value xavg of the Al composition ratio x in the substrate 50 being 0.05 or more and 0.8 or less, based on the above-described average value of the lattice constant.

In the present embodiment, the primary peak as being the satellite peak occurs at a position distant from the zero-order peak by 0.005° or more and 1.850 or less in the diffraction angle 2θ, for example. This corresponds to the period Tp of the Al composition ratio x in the thickness direction of the substrate 50 being 5 nm or more and 2000 nm or less, based on the following formula (D). Alternatively, the primary peak may occur at a position distant from the zero-order peak by 0.0180 or more and 1.85° or less in the diffraction angle 2θ, for example. This corresponds to the period Tp of the Al composition ratio x in the thickness direction of the substrate 50 being 5 nm or more and 500 nm or less, based on the following formula (D).

$$Tp = λ / \{ 2 ( sin {θ}_{1} - sin {θ}_{0} ) \} \qquad ( D )$$

where λ is a wavelength of the Cu Kα1 line,
θ₀ is an angle of the zero-order peak, and
θ₁ is an angle of the primary peak.

### (Characteristic 2 Relating to X-Ray Diffraction Measurement)

In the present embodiment, the crystal strain generated in the regrowth layer 500 is alleviated, which also alleviates crystal strain in the substrate 50 obtained from the regrowth layer 500. Thus, a ratio a/c of an average value of a lattice constant in an a-axis direction to an average value of a lattice constant in a c-axis direction of the substrate 50 is close to the ratio a/c (=0.62) of strain-free AlGaN crystal.

Specifically, the substrate 50 satisfies the following formula (1):

$$0.58 \leq a / c \leq 0.66 \qquad ( 1 )$$

where c is the average value of the lattice constant in the <0001>-axis direction of the substrate 50, as determined based on a diffraction angle of a zero-order peak having the highest diffraction intensity of (0002) plane of AlGaN by X-ray diffraction measurement (2θ-ω scan), and
a is the average value of the lattice constant in a <11-20>-axis direction of the substrate 50, as determined based on the c, and a diffraction angle of a zero-order peak having the highest diffraction intensity of (10-12) plane of AlGaN by X-ray diffraction measurement (2θ-ω scan).

### (Characteristic 3 Relating to X-Ray Diffraction Measurement)

In the present embodiment, the crystal strain generated in the regrowth layer 500 is alleviated, thus enabling the improvement in the crystallinity of the substrate 50 obtained from the regrowth layer 500.

Specifically, a Full Width at Half Maximum (FWHM) of the zero-order peak having the highest diffraction intensity of (0002) plane of AlGaN of the substrate 50 obtained by X-ray rocking curve measurement is, for example, 300 arcsec or less, or may be 100 arcsec or less.

The Full Width at Half Maximum (FWHM) of the zero-order peak having the highest diffraction intensity of (10-12) plane of AlGaN of the substrate 50 obtained by X-ray rocking curve measurement is, for example, 500 arcsec or less, or may be 300 arcsec or less.

The X-ray rocking curve measurement is performed under the following conditions:
X-ray: monochromatic light of Kα1 of Cu obtained from an X-ray source via an X-ray mirror and two crystals on Ge(220)
Gonio radius: 420 mm
Incident slit width: 0.1 mm
Light-receiving slit side: Analyzer crystal

### (Characteristic 4 Relating to X-Ray Diffraction Measurement)

In the present embodiment, the regrowth layer 500 including AlGaN crystal is grown as the continuous film, instead of growing the regrowth layer 500 in the shape of islands, so that the average value xavg of the Al composition ratio x, which is obtained by averaging within a predetermined thickness range from the main surface 50s, is uniform in the main surface 50s of the substrate 50 obtained from the regrowth layer 500.

Specifically, a ratio xc/xo of an average value xc of the Al composition ratio at the center of the main surface 50s of the substrate 50 to an average value xo of the Al composition ratio at a position of 5 mm from the outer periphery toward the center of the main surface 50s of the substrate 50 is 0.9 or more and 1.1 or less, for example.

The average values xo and xc of the Al composition ratio as used herein are determined based on the diffraction angles of the zero-order peak having the highest diffraction intensity of (0002) plane of AlGaN when the X-ray diffraction measurement is performed on the outer peripheral side and center of the main surface of the substrate 50 using the Cu Kα1 line within a range of 35 μm in a penetration length from the main surface, respectively.

### (Dislocation Density)

In the present embodiment, dislocations can be reduced during the growth process of the thick regrowth layer 500. This allows the dislocation density to be reduced in the substrate 50 including AlGaN crystal, obtained from the regrowth layer 500.

Specifically, the dislocation density at the main surface 50s of the substrate 50 is, for example, 3×10⁸ cm⁻² or less, or may be 1×10⁷ cm⁻² or less, 5×10⁶ cm⁻² or less, or 3×10⁶ cm⁻² or less.

### (Conductivity Type)

The conductivity type of the substrate 50 is not particularly limited. However, the substrate 50 of the present embodiment may be of, for example, an n-type. In this case, examples of n-type impurities include Si, germanium (Ge), oxygen (O), and tin (Sn). The concentration of n-type impurities in the substrate 50 may be, for example, 1×10¹⁷ cm⁻³ or more and 1×10¹⁹ cm⁻³ or less.

Alternatively, the substrate 50 of the present embodiment may be of, for example, a p-type. In this case, the substrate 50 may contain, for example, magnesium (Mg). The Mg concentration in the substrate 50 may be, for example, 1×10¹⁶ cm⁻³ or more.

Alternatively, the substrate 50 of the present embodiment may be, for example, semi-insulating. In this case, the substrate 50 may contain, for example, iron (Fe), manganese (Mn) or carbon (C). The concentration of Fe, Mn or C in the substrate 50 may be, for example, 1×10¹⁶ cm ⁻³ or more.

### (3) Summary of Present Embodiment

According to the present embodiment, one or more of the following effects can be obtained.

(a) In the present embodiment, the regrowth layer 500 including AlGaN crystal is grown on the cover layer 400 provided on the porous intermediate layer 300, thus stress applied to the regrowth layer 500 can be alleviated through the porous intermediate layer 300 that is easily deformed.

(b) Furthermore, the regrowth layer 500 including AlGaN crystal is grown on the flat cover layer 400, thus allowing the regrowth layer 500 to be grown as the continuous film while suppressing island-shaped growth of the regrowth layer 500. Thus, the Al composition ratio x can be made uniform in a creepage direction of the regrowth layer 500, across the entire regrowth layer 500.

By growing the regrowth layer 500 as described in (a) and (b), the crystal strain generated in the creepage direction of the regrowth layer 500 including AlGaN can be alleviated. Consequently, the occurrence of cracks in the regrowth layer 500 can be suppressed. Furthermore, the crystallinity of the regrowth layer 500 can be improved.

(c) In the present embodiment, the Al composition ratio x in the regrowth layer 500 periodically changes in a thickness direction of the regrowth layer 500. This can cause the local strain at an unbalanced degree in the thickness direction of the regrowth layer 500. Such local strain with the unbalanced degree in the thickness direction can bend dislocations in a creepage direction, resulting in generating slip in the atomic plane. Generating the slip in the atomic plane releases the crystal strain in the creepage direction of the regrowth layer 500, resulting in further alleviating the crystal strain in the creepage direction. As a result, occurrence of cracks in the regrowth layer 500 can be stably suppressed.

By growing the regrowth layer 500 as described in (a) to (c), a substrate 50 including high-quality AlGaN crystal that is free of cracks can be stably obtained from the regrowth layer 500.

By using the above-described substrate 50 obtained in the present embodiment, high-quality semiconductor devices such as ultraviolet LEDs or ultraviolet LDs, for example, can be produced.

(d) In the present embodiment, an average value xavg of the Al composition ratio x in the regrowth layer 500 (that is, the substrate 50) is 0.05 or more and 0.8 or less. In this way, appropriate crystal strain can be applied to the porous intermediate layer 300 while alleviating crystal strain being applied on the regrowth layer 500.

Specifically, by setting the average value xavg of the Al composition ratio x of the regrowth layer 500 to 0.05 or more, appropriate crystal strain can be applied to the porous intermediate layer 300 as the regrowth layer 500 grows, due to the lattice mismatch between the regrowth layer 500 and the layer located below the regrowth layer 500. This can enhance the fragility of the porous intermediate layer 300. As a result, the peelability of the regrowth layer 500 using, as the boundary, the intermediate layer 300 can be improved.

On the other hand, by setting the average value xavg of the Al composition ratio x of the regrowth layer 500 to 0.8 or less, crystal strain can be prevented from being excessively generated in the porous intermediate layer 300 due to the lattice mismatch between the regrowth layer 500 and the layer located below the regrowth layer 500. This can suppress the disappearance of the voids 360 in the intermediate layer 300 and can prevent the adhesion between the regrowth layer 500 and the layer located below the regrowth layer 500. As a result, the degradation in the peelability of the regrowth layer 500 using, as the boundary, the intermediate layer 300 can be suppressed.

As described above, the substrates 50 including AlGaN crystal can be obtained stably from the viewpoint of the peelability of the regrowth layer 500.

(e) In the present embodiment, one period of the Al composition ratio x in the thickness direction of the regrowth layer 500 (that is, the substrate 50) may be 5 nm or more and 2000 nm or less, or 5 nm or more and 500 nm or less.

By setting the one period of the Al composition ratio x in the thickness direction in the regrowth layer 500 to 5 nm or more, a portion where the Al composition ratio x changes can be stably formed. In this way, the slip in the atomic plane can be stably generated in the portion where the Al composition ratio x changes. As a result, the crystal strain in a creepage direction of the regrowth layer 500 can be stably alleviated.

On the other hand, by setting the one period of the Al composition ratio x in the thickness direction in the regrowth layer 500 to 2000 nm or less, a sufficient number of periods in which the Al composition ratio x changes can be ensured in the regrowth layer 500. In other words, a sufficient number of portions in which slips may occur in an atomic plane can be formed in the regrowth layer 500. Thus, the crystal strain in the creepage direction of the regrowth layer 500 can be stably alleviated.

Further, by setting the one period of the Al composition ratio x in the thickness direction in the regrowth layer 500 to 500 nm or less, sufficient interval can be ensured between the zero-order peak and the satellite peak in a diffraction pattern obtained by an X-ray diffraction 2θ-ω scan measurement on the substrate 50 obtained from the regrowth layer 500. Thus, periodic structure for the Al composition ratio x in the substrate 50 can be stably confirmed after the production of the substrate 50.

(f) In the present embodiment, a difference xmax-xmin between a maximum value and a minimum value of the Al composition ratio x in the regrowth layer 500 (that is, the substrate 50) is 0.2 xavg or more and xavg or less, where xavg is the average value of the Al composition ratio x.

By setting xmax-xmin in the regrowth layer 500 to 0.2 xavg or more, local strain can be generated at an appropriate changing degree in the thickness direction of the regrowth layer 500. In this way, the slip in the atomic plane can be stably generated. As a result, the crystal strain in the creepage direction of the regrowth layer 500 can be stably alleviated.

On the other hand, by setting the xmax-xmin in the regrowth layer 500 to xavg or less, the local strain of unbalanced degree can be prevented from being excessively large in the thickness direction of the regrowth layer 500. Consequently, the occurrence of cracks can be more stably suppressed.

### (4) Modification Example of Embodiment

The above embodiment can be modified as needed, as described in the following modification examples. Hereinafter, only components that differ from those in the above embodiment will be described. Components that are substantially the same as those in the above embodiment are denoted by the same reference characters, and descriptions thereof are omitted.

### Modification Example 1

In a cover layer formation step S40 of Modification Example 1, for example, crystal represented by the composition formula of AlₓGa₁₋ₓN may be grown as the cover layer 400. At this time, the Al composition ratio x in the cover layer 400 is, for example, more than 0 and 1 or less, or may be 0.05 or more and 0.8 or less.

According to Modification Example 1, AlGaN crystal is grown as the cover layer 400, thereby allowing the regrowth layer 500 to be grown homo-epitaxially on the cover layer 400. This can stably grow the regrowth layer 500 with good crystallinity.

### Modification Example 2

In a first regrowth step S62 of Modification Example 2, the growth temperature may be gradually increased from the first growth temperature T1 to the second growth temperature T2 while growing the first regrowth layer 520.

According to Modification Example 2, the rate of temperature increase from the first growth temperature T1 to the second growth temperature T2 can be slowed down. As a result, cracks in the group III nitride crystal layer above the intermediate layer 300 that would be caused by the temperature increase step from the first growth temperature T1 to the second growth temperature T2 can be stably suppressed.

### Modification Example 3

In a regrowth step S60 of Modification Example 3, the growth temperature of the regrowth layer 500 may be adjusted in one stage. That is, the temperature of the seed substrate 10 may be directly increased from room temperature to a growth temperature of the regrowth step S60 (which corresponds to the second growth temperature T2 described above).

According to Modification Example 3, the first regrowth step S62 can be omitted. As a result, the manufacturing process can be shortened.

### Modification Example 4

Similarly to the second regrowth step S64, the Al composition ratio x may be periodically changed in the thickness direction of the first regrowth layer 520 in a first regrowth step S62 of Modification Example 4.

In the first regrowth layer 520, an average value of the Al composition ratio x, a period of the Al composition ratio x in the thickness direction, and a difference between a maximum value and a minimum value of the Al composition ratio x may be similar to those in the second regrowth layer 540.

According to Modification Example 4, by forming periodic structure for the Al composition ratio x also in the first regrowth layer 520, crystal strain generated in a creepage direction of the first regrowth layer 520 can be stably alleviated.

### Modification Example 5

In Modification Example 5, the regrowth layer 500 may have two types of layers having different Al composition ratios x from each other as described below, alternately in a thickness direction.

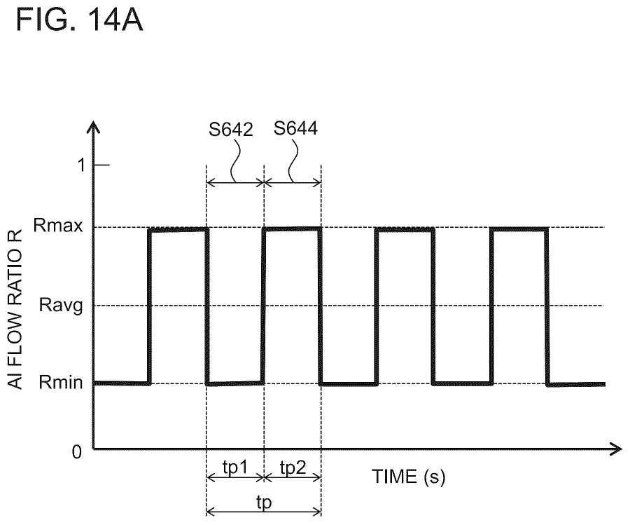

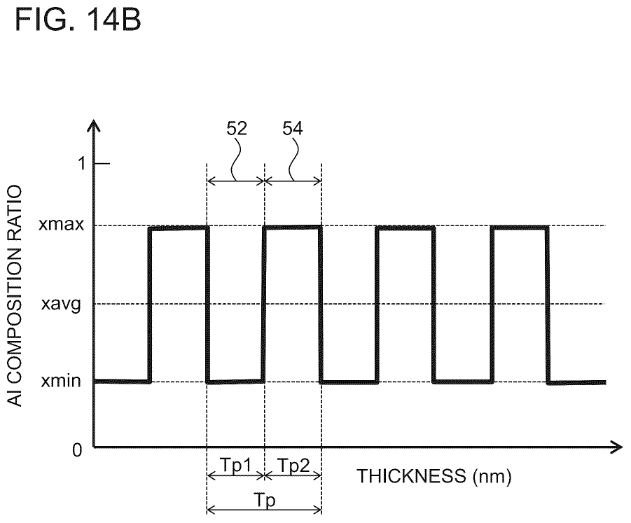

As illustrated in FIG. 14A, in the second regrowth step S64 in Modification Example 5,
a cycle including:
a step S642 for forming a first composition layer by adjusting an Al flow ratio R to a minimum value Rmin; and
a step S644 for forming a second composition layer on the first composition layer by adjusting the Al flow ratio R to a maximum value Rmax,
is repeated.

In the step S642 for forming the first composition layer, the Al flow ratio R is made constant at the minimum value Rmin across time tp1. In the step S644 for forming the second composition layer, the Al flow ratio R is made constant at the maximum value Rmax across time tp2.

As illustrated in FIG. 14B, the substrate 50 obtained from the regrowth layer 500 in Modification Example 5 has a first composition layer 52 in which the Al composition ratio x is a minimum value xmin, and a second composition layer 54 in which the Al composition ratio x is a maximum value xmax. The Al composition ratio x in the first composition layer 52 is constant across a thickness direction of the first composition layer 52. The Al composition ratio x in the second composition layer 54 is constant across a thickness direction of the second composition layer 54.

In Modification Example 5, an average value xavg of the Al composition ratio x in the substrate 50, a period Tp of the Al composition ratio x in the thickness direction of the substrate 50, and a difference xmax-xmin between a maximum value and a minimum value of the Al composition ratio x in the substrate 50 may be similar to those in the above-described embodiments.

In Modification Example 5, the period Tp for the Al composition ratio x in the thickness direction of the substrate 50 is a total thickness of a thickness Tp1 of the first composition layer 52 and a thickness Tp2 of the second composition layer 54. The thickness Tp1 of the first composition layer 52 and the thickness Tp2 of the second composition layer 54 may be the same, or different from each other.

According to Modification Example 5, an interface at which the Al composition ratio x changes can be clearly formed between the first composition layer 52 and the second composition layer 54. In this way, the slip in the atomic plane can be stably generated in the interface where the Al composition ratio x changes. As a result, crystal strain generated in the regrowth layer 500 can be stably alleviated.

### Other Embodiments of Present Disclosure

Embodiments of the present disclosure have been specifically described above. However, the present disclosure is not limited to the embodiments described above, and can be modified in various ways without departing from its gist.

In the embodiments described above, the base layer formation step S20 is performed, but the base layer formation step S20 may not be performed. That is, the base layer 200 may be eliminated. In the intermediate layer formation step S30, the intermediate layer 300 may be formed directly on the base substrate 100.

In the embodiments described above, an upper layer of the base layer 200 and the intermediate layer 300 each includes GaN crystal, but the present disclosure is not limited to this case. Each layer is not limited to GaN crystal, but may include, for example, group III nitride crystal such as aluminum nitride (AlN), aluminum gallium nitride (AlGaN), indium nitride (InN), indium gallium nitride (InGaN), and aluminum indium gallium nitride (AlInGaN), that is, crystal represented by a composition formula of InₓAl_{y}Ga_{1-x-y}N (where 0≤x≤1, 0≤y≤1, 0≤x+y≤1).

In the embodiments described above, the base substrate 100 includes a material different from a group III nitride, but the present disclosure is not limited to this case. The base substrate 100 may be a free-standing substrate including, for example, group III nitride crystal.

In the embodiments described above, the upper layer of the base layer 200, the intermediate layer 300, the cover layer 400, and the regrowth layer 500 each contain Si as the n-type impurity, but at least any one of the upper layer of the base layer 200, the intermediate layer 300, the cover layer 400, and the regrowth layer 500 may contain, for example, O or Ge as the n-type impurity.

In the embodiments described above, the above-described respective vapor phase growth methods are used as growth methods for the base layer 200, the intermediate layer 300, the cover layer 400, and the regrowth layer 500, but the present disclosure is not limited to this case. A metal organic vapor phase epitaxy (MOVPE) method may be used as the growth method for at least any one of the base layer 200, the intermediate layer 300, the cover layer 400, and the regrowth layer 500. Alternatively, a growth method other than the vapor phase growth method may be used as the growth method for at least any one of the base layer 200, the intermediate layer 300, the cover layer 400, and the regrowth layer 500.

In the embodiments described above, the first regrowth layer 520 is grown three-dimensionally after the growth in the step-flow growth mode in the initial stage of the growth of the first regrowth layer 520, but the present disclosure is not limited to this case. The growth of the first regrowth layer 520 in the step-flow growth mode may be maintained.

### Examples

The following is a description of experimental results that support the effectiveness of the above-described embodiments.

### (1) Fabrication of Samples

The following three samples were fabricated.

### [Sample A]

A nitride crystal substrate of Sample A was fabricated by the production method of the embodiment described above, according to the following procedure.

### (Base Substrate Preparation Step)

Abase substrate for obtaining a seed substrate was prepared.
Base substrate: Sapphire substrate
Surface orientation of main surface of base substrate: +c-plane
Diameter of base substrate: 3 inches (76.2 mm)
Thickness of base substrate: 430 μm

### (Base Layer Formation Step)

An AlN buffer layer and a GaN layer were formed on the base substrate in this order as the base layer by the HVPE method under the following conditions.
Growth temperature of base layer: 1055° C.
Thickness of AlN buffer layer and GaN layer: 100 nm and 4 μm, respectively Carrier concentration in GaN layer as base layer: about 1×10¹⁸ cm⁻³

### (Intermediate Layer Formation Step)

Next, a Si-doped GaN layer was grown as the intermediate layer on the base layer by the HVPE method under the following conditions.
Growth temperature of intermediate layer: 1055° C.
Thickness of intermediate layer: 3000 nm
Carrier concentration in intermediate layer: 6×10¹⁸ cm⁻³

### (Cover Layer Formation Step)

Next, a GaN layer was grown as the cover layer on the base layer by the HVPE method under the following conditions.
Growth temperature of cover layer: 1055° C.
Thickness of cover layer: 150 nm
Carrier concentration in cover layer: about 5×10¹⁷ cm⁻³

### (Porous Step)

Next, the intermediate layer was made porous through dislocations in the cover layer by performing the electrochemical treatment under the following conditions.
Electrolyte temperature: room temperature (23° C.)
Treatment voltage: 20 V
Treatment current: 100 mA as the maximum
Treatment time: 10 min

### (First Regrowth Step)

Next, an Al_{0.6}Ga_{0.4}N layer was grown as the first regrowth layer on the cover layer by the HVPE method under the following conditions.
First growth temperature: 835° C.
Thickness of first regrowth layer: 50 μm

### (Second Regrowth Step)

Next, an AlGaN layer was grown as the second regrowth layer on the first regrowth layer in the same chamber as in the first regrowth step while periodically changing the Al composition ratio in the thickness direction.
Second growth temperature: 1055° C.
Adjustment sequence of the Al flow ratio R: FIG. 8
Average value Ravg of the Al flow ratio R: 0.6
Minimum value Rmin of the Al flow ratio R: 0.45
Maximum value Rmax of the Al flow ratio R: 0.75
Period tp by which the Al flow ratio R is changed: the period Tp for the Al composition ratio x in the thickness direction of the second regrowth layer was adjusted to about 30 nm.
Total thickness of regrowth layers: 1 mm

### (Peeling Step)

The regrowth layer was peeled off from the base substrate as the temperature decreased after the regrowth step.

### (Post-Treatment Step)

A nitride crystal substrate was formed by slicing the peeled regrowth layer. After the slicing, both surfaces of the nitride crystal substrate were polished. Further, the outer periphery of the nitride crystal substrate was beveled. Consequently, as Sample Al, a nitride crystal substrate including AlGaN crystal with a diameter of 2 inches (50.8 mm) and a thickness of 430 μm was obtained.

[Sample B1 (Direct Growth on GaN Free-Standing Substrate)]

In the fabrication of Sample B1, a GaN free-standing substrate was used as the base substrate. An Al_{0.6}Ga_{0.4}N layer with a thickness of 1 mm was grown as the main growth layer directly on the GaN free-standing substrate by the HVPE method under the same conditions as those of the second regrowth layer in Sample A. This produced a stack of Sample B1.

[Sample B2 (VAS method)]

In the fabrication of Sample B2, the VAS method was employed. First, a template was prepared on a sapphire substrate with a diameter of 3 inches, the template including a GaN layer of 300 nm in thickness with voids, and a mesh-shaped TiN layer of 20 nm in thickness in this order. Next, an Al_{0.6}Ga_{0.4}N layer with a thickness of 1 mm was grown as a main growth layer on the above GaN and TiN layers by the HVPE method under the same conditions as those of the second regrowth layer in Sample A. The main growth layer was then peeled off from the sapphire substrate using, as the boundary, the GaN layer with the voids. This formed an Al_{0.6}Ga_{0.4}N layer of Sample B2.

### (2) Evaluation [Optical Microscope]

Each sample was observed with an optical microscope.

[X-ray diffraction 2θ-ω scan measurement 1]

An X-ray diffraction 2θ-ω scan measurement was performed on the nitride crystal substrate of Sample Aby using a Cu Kα1 line (wavelength: 0.15405 nm), under a condition under which diffraction of the (0002) plane of AlGaN is measured by symmetric reflection.

The X-ray diffraction 2θ- scan measurement 1 was performed at each of the following measurement positions on the nitride crystal substrate of Sample A.
Center of the main surface of the substrate
Points set at intervals of 1 cm on a straight line extending along the m-axis direction and passing through the center of the main surface of the substrate
Points set at intervals of 1 cm on another straight line along the a-axis direction orthogonal to the m-axis direction, which also passes through the center of the main surface of the substrate
Point set at a position of 5 mm from the outer periphery toward the center of the main surface of the substrate

As a result of the measurement, an average value of the lattice constant c in a <0001>-axis direction of the substrate was determined based on a diffraction angle 2θ of a zero-order peak having the highest diffraction intensity of the (0002) plane of AlGaN. Based on the average value of the lattice constant c, an average value xavg of the Al composition ratio x in the nitride crystal substrate of Sample A was determined (by averaging within a range of 35 m in an X-ray penetration length).

Based on a diffraction angle of the zero-order peak and a diffraction angle of the primary peak, the period Tp for the Al composition ratio x in the thickness direction of the nitride crystal substrate in Sample A was determined using the above-described formula (D).

Further, a ratio xc/xo was determined, based on an average value xc of the Al composition ratio at the center of the main surface of the substrate to an average value xo of the Al composition ratio at a position of 5 mm from the outer periphery toward the center of the main surface of the substrate.

### [X-Ray Diffraction 2θ-ω Scan Measurement 2]

An X-ray diffraction 2θ-ω scan measurement was performed on the nitride crystal substrate of Sample Aby using a Cu Kα1 line, under a condition under which diffraction of the (10-12) plane of AlGaN is measured by asymmetric reflection.

The X-ray diffraction 2θ-ω scan measurement 2 was performed at each measurement position similar to that described above for the X-ray diffraction 2θ-ω scan measurement 1.

As a result of the measurement, an average value of the lattice constant a in a <11-20>-axis direction of the substrate was determined based on a diffraction angle 2θ of a zero-order peak having the highest diffraction intensity of the (10-12) plane of AlGaN.

### [X-Ray Rocking Curve Measurement 1]

The Full Width at Half Maximum (FWHM) of a zero-order peak having the highest diffraction intensity of the (0002) of AlGaN was determined by performing X-ray rocking curve measurement at each of the above-described measurement positions on the nitride crystal substrate of Sample A.

[X-Ray Rocking Curve Measurement 2]

The Full Width at Half Maximum (FWHM) of a zero-order peak having the highest diffraction intensity of the (10-12) of AlGaN was determined by performing X-ray rocking curve measurement at each of the above-described measurement positions on the nitride crystal substrate of Sample A.

[Multiphoton excitation microscope]

The dislocation density was determined by observing the main surface at each of the above-described measurement positions of the nitride crystal substrate of Sample A in a field of view of 250 μm square with a multiphoton excitation microscope.

### (3) Results

The results for Samples A, B1 and B2 will be described below.

### [Sample B1]

In Sample B1, cracks occurred in the main growth layer after the growth of the main growth layer on the GaN free-standing substrate. In Sample B1, it is considered that the cracks occurred in the main growth layer due to the lattice mismatch between the GaN free-standing substrate and the main growth layer including AlGaN crystal.

### [Sample B2]

In Sample B2, cracks occurred in a part of the main growth layer peeled off from the sapphire substrate. In Sample B2, the movement of Al atoms was reduced when island-shaped AlGaN crystal was grown three-dimensionally on the GaN layer with voids and the mesh-shaped TiN layer. This led to variations in Al composition ratio in the plane. Due to the variations in Al composition ratio, crystal strain was generated in the thick main growth layer including AlGaN crystal. As a result, it is considered that cracks occurred in the main growth layer in Sample B2.

### [Sample A]

In Sample A, no cracks occurred in either the peeled regrowth layer or the nitride crystal substrate obtained from the regrowth layer.

FIG. 13 illustrates a diffraction pattern obtained by an X-ray diffraction 2θ-ω scan measurement 1 on the center of the main surface of the nitride crystal substrate of Sample A. As illustrated in FIG. 13, the diffraction pattern of Sample A has a fringe. In this way, it was confirmed in Sample A that the Al composition ratio x in the nitride crystal substrate periodically changes in the thickness direction of the substrate.

As a result of the measurement, the average value of the lattice constant c of the nitride crystal substrate of Sample A was 0.5065 nm as determined based on the diffraction angle 2θ of the zero-order peak having the highest diffraction intensity of the (0002) plane of AlGaN. An average value xavg of the Al composition ratio x in the nitride crystal substrate of Sample A was 0.593 as determined based on the average value of the lattice constant c.

The period Tp for the Al composition ratio x in the thickness direction of the nitride crystal substrate in Sample A was 30.9 nm as determined using the above-described formula (D), and based on the diffraction angle of the zero-order peak and the diffraction angle of the primary peak.

Further, from the results of measurements taken at each of the measurement positions described above, it was confirmed that the following properties for the nitride crystal substrate of Sample A were obtained.
xavg: 0.56 to 0.60
Ratio xc/xo: about 1.07
Period Tp: 28 to 33 nm

0.58≤a/c≤0.66 (1)
FWHM of the (0002) plane diffraction <250 arcsec
FWHM of the (10-12) plane diffraction <450 arcsec
Dislocation density <3×10⁶ cm⁻²

As illustrated in the above results, by growing the regrowth layer including the AlGaN crystal on the flat cover layer provided on the porous intermediate layer, the crystal strain generated in the creepage direction of the regrowth layer was alleviated in Sample A. Further, in Sample A, periodically changing the Al composition ratio x in the thickness direction in the regrowth layer enabled the crystal strain generated in the creepage direction of the regrowth layer to be alleviated further. As a result, it was confirmed that a nitride crystal substrate including high-quality AlGaN crystalfree of cracks was stably obtained in Sample A.

### Supplementary Descriptions

Hereinafter, aspects of the present disclosure will be supplementarily described.

### Supplementary Description 1

A nitride crystal substrate including crystal represented by a composition formula of AlₓGa₁₋ₓN, wherein
an Al composition ratio x in the composition formula is more than 0 and 1 or less, and
the Al composition ratio x periodically changes in a thickness direction of the nitride crystal substrate.

### Supplementary Description 2

The nitride crystal substrate according to supplementary description 1, wherein
an average value of the Al composition ratio x is 0.05 or more and 0.8 or less.

### Supplementary Description 3

The nitride crystal substrate according to supplementary description 1 or 2, wherein
one period of the Al composition ratio x in the thickness direction of the nitride crystal substrate is 5 nm or more and 2000 nm or less.

### Supplementary Description 4

The nitride crystal substrate according to any one of supplementary descriptions 1 to 3, wherein
a difference between a maximum value and a minimum value of the Al composition ratio x is 0.2 xavg or more and xavg or less,
where xavg is an average value of the Al composition ratio x.

### Supplementary Description 5

The nitride crystal substrate according to any one of supplementary descriptions 1 to 4, wherein
a thickness of the nitride crystal substrate is 300 m or more and 2 mm or less, and
the number of periods of the Al composition ratio x in the thickness direction of the nitride crystal substrate is 150 or more and 4×10⁵ or less.

### Supplementary Description 6

The nitride crystal substrate according to any one of supplementary descriptions 1 to 5, wherein
the nitride crystal substrate has
minimum points at which the Al composition ratio x has a minimum value, and
maximum points at which the Al composition ratio x has a maximum value
alternately in a thickness direction, and
the Al composition ratio x gradually increases from each of the minimum points toward each of the maximum points in the thickness direction of the nitride crystal substrate.

### Supplementary Description 7

The nitride crystal substrate according to any one of supplementary descriptions 1 to 5, wherein
the nitride crystal substrate has
first composition layers in which the Al composition ratio x has a minimum value, and
second composition layers in which the Al composition ratio x has a maximum value,
the first composition layers and the second composition layers being provided alternately in a thickness direction.

### Supplementary Description 8

The nitride crystal substrate according to any one of supplementary descriptions 1 to 7, wherein
when using a Cu Kα1 line to perform an X-ray diffraction 2θ-ω scan measurement on the nitride crystal substrate under a condition under which diffraction of the (0002) plane of AlGaN is measured,
a diffraction pattern obtained by the 2θ-ω scan measurement on the nitride crystal substrate has
a zero-order peak occurring within a range of 34.620 or more and 35.73° or less in a diffraction angle 2θ, and
a satellite peak occurring at a position distant from the zero-order peak by 0.005° or more and 1.85° or less in a diffraction angle 2θ.

### Supplementary Description 9

The nitride crystal substrate according to any one of supplementary descriptions 1 to 8, wherein
the nitride crystal substrate satisfies the following formula (1):

0.58≤a/c≤0.66 (1)
where c is an average value of a lattice constant in a <0001>-axis direction of the nitride crystal substrate, as determined based on a diffraction angle of a zero-order peak having a highest diffraction intensity of (0002) plane of AlGaN in an X-ray diffraction measurement, and
a is an average value of a lattice constant in a <11-20>-axis direction of the nitride crystal substrate, as determined based on the c and a diffraction angle of a zero-order peak having a highest diffraction intensity of (10-12) plane of AlGaN in an X-ray diffraction measurement.

### Supplementary Description 10

The nitride crystal substrate according to any one of supplementary descriptions 1 to 9, wherein
the nitride crystal substrate has a diameter of 25 mm or more and is free of cracks.

### Supplementary Description 11

The nitride crystal substrate according to any one of supplementary descriptions 1 to 10, wherein
a full width at half maximum of a zero-order peak having the highest diffraction intensity of the (0002) plane of AlGaN obtained in X-ray rocking curve measurement is 300 arcsec or less, and
a full width at half maximum of a zero-order peak having the highest diffraction intensity of the (10-12) plane of AlGaN obtained in X-ray rocking curve measurement is 500 arcsec or less.

### Supplementary Description 12

A laminate including:
a nitride crystal substrate; and
a semiconductor layer provided on the nitride crystal substrate and including group III nitride crystal, wherein
the nitride crystal substrate includes crystal represented by a composition formula of AlₓGa₁₋ₓN,
an Al composition ratio x in the composition formula of the nitride crystal substrate is more than 0 and 1 or less, and
the Al composition ratio x of the nitride crystal substrate periodically changes in a thickness direction of the nitride crystal substrate.

### Supplementary Description 13

A production method for a nitride crystal substrate, the method including:
(a) preparing a base substrate;
(b) forming an intermediate layer above the base substrate, the intermediate layer including n-type group III nitride crystal;
(c) forming a cover layer on the intermediate layer, the cover layer including group III nitride crystal having a carrier concentration lower than a carrier concentration of the intermediate layer;
(d) making the intermediate layer porous through dislocations in the cover layer by performing electrochemical treatment, while maintaining a surface condition of the cover layer;
(e) epitaxially growing a regrowth layer on the cover layer, the regrowth layer including group III nitride crystal; and
(f) peeling off the regrowth layer from the base substrate by using, as a boundary, at least a portion of the intermediate layer made porous, wherein
in (e),
crystal represented by a composition formula of AlₓGa₁₋ₓN is grown as the regrowth layer, an Al composition ratio x in the composition formula being more than 0 and 1 or less, and
the Al composition ratio x is periodically changed in a thickness direction of the regrowth layer.

### Supplementary Description 14

The production method for the nitride crystal substrate according to the supplementary description 13, wherein
in (e),
crystal strain generated in a creepage direction of the regrowth layer is alleviated more than in a case where (d) is not performed.

### Supplementary Description 15

The production method for the nitride crystal substrate according to the supplementary description 13 or 14, wherein
in (e),
the regrowth layer is grown in a step-flow growth mode at least in an initial stage of the growth of the regrowth layer.

### Supplementary Description 16

The production method for the nitride crystal substrate according to any one of the supplementary descriptions 13 to 15, wherein
in (c),
GaN crystal is grown as the cover layer.

### Supplementary Description 17

The production method for the nitride crystal substrate according to any one of the supplementary descriptions 13 to 15, wherein
in (c),
crystal represented by a composition formula of AlₓGa₁₋ₓN is grown as the cover layer, an Al composition ratio x in the composition formula being more than 0 and 1 or less.

### Supplementary Description 18

The production method for the nitride crystal substrate according to any one of the supplementary descriptions 13 to 17, wherein
(e) involves:
(e1) growing a first regrowth layer on the cover layer at a first growth temperature; and
(e2) growing a second regrowth layer on the first regrowth layer at a second growth temperature, and in (e1),
the first growth temperature is set lower than the second growth temperature.

### REFERENCE SIGNS LIST

10 Seed substrate for nitride crystal growth
Peeled intermediate
50 Nitride crystal substrate
100 Base substrate
120 Main surface
200 Base layer
300 Intermediate layer
360 Void
400 Cover layer
500 Regrowth layer
520 First regrowth layer
540 Second regrowth layer
510 c-Plane
810 Electrolyte
820 Process tank
840 Power source
842 Anode
844 Cathode
860 Current meter

What is claimed is:

1. A nitride crystal substrate comprising crystal represented by a composition formula of AlₓGa₁₋ₓN, wherein
an Al composition ratio x in the composition formula is more than 0 and 1 or less, and
the Al composition ratio x periodically changes in a thickness direction of the nitride crystal substrate.

2. The nitride crystal substrate according to claim 1, wherein
an average value of the Al composition ratio x is 0.05 or more and 0.8 or less.

3. The nitride crystal substrate according to claim 1, wherein
one period of the Al composition ratio x in the thickness direction of the nitride crystal substrate is 5 nm or more and 2000 nm or less.

4. The nitride crystal substrate according to claim 1, wherein
a difference between a maximum value and a minimum value of the Al composition ratio x is 0.2 xavg or more and xavg or less,
where xavg is an average value of the Al composition ratio x.

5. The nitride crystal substrate according to claim 1, wherein
when using a Cu Kα1 line to perform an X-ray diffraction 2θ-ω scan measurement on the nitride crystal substrate under a condition under which diffraction of the (0002) plane of AlGaN is measured,
a diffraction pattern obtained by the 2θ-ω scan measurement on the nitride crystal substrate has
a zero-order peak occurring within a range of 34.62° or more and 35.73° or less in a diffraction angle 2θ, and
a satellite peak occurring at a position distant from the zero-order peak by 0.005° or more and 1.85° or less in a diffraction angle 2θ.

6. The nitride crystal substrate according to claim 1, wherein
the nitride crystal substrate satisfies the following formula (1):
0.58≤a/c≤0.66 (1)
where c is an average value of a lattice constant in a <0001>-axis direction of the nitride crystal substrate, as determined based on a diffraction angle of a zero-order peak having a highest diffraction intensity of (0002) plane of AlGaN in an X-ray diffraction measurement, and
a is an average value of a lattice constant in a <11-20>-axis direction of the nitride crystal substrate, as determined based on the c and a diffraction angle of a zero-order peak having a highest diffraction intensity of (10-12) plane of AlGaN in an X-ray diffraction measurement.

7. A production method for a nitride crystal substrate, the method comprising:
(a) preparing a base substrate;
(b) forming an intermediate layer above the base substrate, the intermediate layer including n-type group III nitride crystal;
(c) forming a cover layer on the intermediate layer, the cover layer including group III nitride crystal having a carrier concentration lower than a carrier concentration of the intermediate layer;
(d) making the intermediate layer porous through dislocations in the cover layer by performing electrochemical treatment, while maintaining a surface condition of the cover layer;
(e) epitaxially growing a regrowth layer on the cover layer, the regrowth layer including group III nitride crystal; and
(f) peeling off the regrowth layer from the base substrate by using, as a boundary, at least a portion of the intermediate layer made porous, wherein
in (e),
crystal represented by a composition formula of AlₓGa₁₋ₓN is grown as the regrowth layer, an Al composition ratio x in the composition formula being more than 0 and 1 or less, and
the Al composition ratio x is periodically changed in a thickness direction of the regrowth layer.
